(19) United States
(12) Patent Application Publication
(10) Pub. No.: US 2007/0164293 A1
(43) Pub. Date: Jul. 19, 2007

(54) LIGHT-EMITTING DEVICE AND METHOD FOR THE PRODUCTION OF LIGHT-EMITTING DEVICE

(75) Inventors: Takafumi HAMANO, Fukuoka (JP); Shinya YAMAMOTO, Fukuoka (JP); Hiroshi SHIROUZU, Fukuoka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/623,596

(22) Filed: Jan. 16, 2007

(30) Foreign Application Priority Data
Jan. 13, 2006 (JP) 2006/005910
Mar. 14, 2006 (JP) 2006/068797
Apr. 20, 2006 (JP) 2006/117109

(51) Int. Cl. H01L 33/00

(52) U.S. Cl. 257/79

(57) ABSTRACT

The invention concerns a light-emitting device comprising an electroluminescent element as a light source and a light-detecting element disposed superimposed on the electroluminescent element for detecting the quantity of light emitted by the electroluminescent element to generate an electric signal for use in the correction of the quantity of light emitted, wherein the light-detecting element has a semiconductor island region A_{R} formed larger than a light-projecting region A_{LE} and the thickness of the light-emitting layer in the light-projecting region A_{LE} is uniform.

### BACKGROUND OF THE INVENTION

1. Field of the Invention

The present invention relates to a light-emitting device for use in display devices such as light head and display to be incorporated in image forming device and a method for the production thereof.

2. Description of the Related Art

In recent years, the reduction of size and cost of image forming devices such as facsimile and printer have been in rapid progress. Thus, the reduction of size and cost of elements constituting these devices is now under way.

Examples of the method for forming an image using an image forming device include a heat-sensitive recording method which comprises making the use of the heat of a heat-generating element to cause heat transfer by which an image is formed, an ink jet method which comprises spreading a fine particulate ink over a printing material, and a method involving the use of light. Among these image forming devices, the image forming device which employs light allows a photoreceptor to be irradiated with and exposed to light modulated according to image data, whereby a toner electrostatically attached to the photoreceptor is transferred to a printing object such as recording paper to form an image thereon. It is known that the light with which the photoreceptor is irradiated can be normally controlled by a method which comprises using a rotary polygon mirror to introduce light emitted by a semiconductor laser into the photoreceptor or a method which comprises using an exposure device called light head comprising a plurality of micro light head. Among these devices, the light head comprises a light source, a circuit for driving and controlling the light source, etc. As the light source there is mainly used a light-emitting diode.

In order to save the space of the light head, the light source or the circuit for driving and controlling the light source needs to be reduced in size. The spread of thin film transistors has made it easy to realize the reduction of size of driving/controlling circuit. On the other hand, the light-emitting diode which is a light source is supplied in the form of chip part. Therefore, in order to form the light head, it is necessary that a large number of semiconductor chips be disposed on a substrate to a high precision, normally requiring a complicated production process. Accordingly, when this production process is effected, it is difficult to avoid the rise of production cost.

As a means for accomplishing the reduction of size of the light source while suppressing the rise of production cost there has been proposed a light head comprising as a light source an electroluminescent element such as organic electroluminescent element and inorganic electroluminescent element. Electroluminescence is a light-emitting (luminescence) phenomenon developed when an electric field is applied to a luminescent material. An organic electroluminescent element is a light-emitting device which allows the application of a potential difference to a light-emitting layer made of an organic material constituting the element so that electron and hole are injected into the light-emitting layer where they are then combined to produce an energy that is then utilized in the luminescence of the organic molecule to emit light. On the other hand, an inorganic electroluminescent element is the same as the organic electroluminescent element except that the light-emitting layer constituting the element is made of an inorganic material instead of organic material. The inorganic electroluminescent element is a so-called intrinsic electroluminescent element which allows the application of an electric field causing the injection of charge to emit light as opposed to the organic electroluminescent element which allows the injection of charge to emit light. The inorganic electroluminescent element is normally driven upon application of an ac electric field.

Referring to the basic configuration of the organic electroluminescent element or inorganic electroluminescent element, an organic material layer or inorganic material layer is merely provided interposed between an anode and a cathode. Since the formation of the electrode and the organic layer or inorganic layer in a thin layer for the purpose of reducing the size of the device can be easily carried out by a processing technique such as chemical vapor phase method, sputtering method, vacuum metallizing method, spin coating method, ink jet method and printing method, the rise of production cost can be suppressed as compared with the case where the size of the laser device or light-emitting diode is reduced.

Examples of the use of an organic electroluminescent element among these electroluminescent elements as a light head are disclosed in JP-A-2002-144634 and JP-A-2002-178560. In JP-A-2002-144634, the configuration of light head is described with reference to light-emitting/detecting element. In JP-A-2002-178560, the configuration of light head is described with reference to pixel. The light-emitting portion disclosed in both the patent references each are a laminate comprising a light-emitting layer composed of an organic electroluminescent element, a light-detecting element for use in the correction of quantity of light, a thin film transistor which is a circuit for driving and controlling the light-emitting layer, etc. and have the same configuration in principle. Both the patent references concern a system allowing the emission of light at the driving/controlling circuit side. Such a light emission system is called bottom emission. In these patent references, a light-detecting element having a smaller light-receiving region than the light-emitting region of the light-emitting layer is provided to prevent the obstruction of light outputted from the bottom.

FIG. 22 is a sectional view illustrating the configuration of a related art light head, particularly the peripheral configuration of a light-emitting element provided on the light head.

As shown in FIG. 22, a light-emitting element (electroluminescent element 110) which is a light source in light head constitutes a laminate of a several material layers. The light head comprises a base coat layer 101 provided on a glass substrate 100. On the base coat layer 101 are formed a driving circuit, an electroluminescent element 110 which is a light source and a driving circuit therefor. On a part of the base coat layer 101 is provided a light-detecting element 120. In this arrangement, an element region Aᵣ which is the light-receiving region of the light-detecting element 120 is formed smaller than a light-projecting region A_{LE} so that the light outputted from the light-projecting region A_{LE} cannot be blocked by the element region Aᵣ. Accordingly, the surface of the laminate which has been so far formed at this step has a level difference formed thereon that is caused by the light-detecting element 120. Subsequently, an interlayer insulating film 103 made of silicon oxide film is formed on the laminate. However, the aforementioned level difference due to the presence of the light-detecting element 120 makes it difficult to form the interlayer insulating film 103 to a constant thickness. The resulting interlayer insulating film 103 is a layer which is convex-shaped following the shape of the light-detecting element 120. The various layer formed on the interlayer insulating film 103 thus formed, too, have a convex shape following the shape of the light-detecting element 120. Accordingly, the thickness of the light-emitting layer 112 is smaller at the convex portion or its edge portion than the other areas. Thus, the thickness of the light-emitting layer 112 is not constant at the light-projecting region A_{LE}. When a voltage is applied between the anode 111 and the cathode 113 to give a potential difference to the light-emitting layer 112 under these conditions, electric current is concentrated onto the thin portion of the light-emitting layer 112. As a result, the surface of the thin portion of the light-emitting layer 112 exhibits a higher brightness than the other surfaces, causing ununiformity in emission distribution (in-plane distribution) in one electroluminescent element 110.

When the emission distribution is uneven, the shape of light spots to be exposed are uneven, resulting in the dispersion of effective area (area contributing to development) of electrostatic latent image formed by exposure among the pixels. This causes the occurrence of density unevenness that deteriorates image quality.

Further, the electroluminescent element 110 such as organic electroluminescent element and inorganic electroluminescent element deteriorates at the region where the concentration of electric current causes generation of high brightness faster than at the other regions. The life of the electroluminescent element 110 is governed by the region which deteriorates most drastically. Therefore, when the emission distribution is uneven, the life of the electroluminescent element 110 is shorter than when the emission distribution is uniform.

Further, when the emission distribution is uneven, the various parts in one electroluminescent element 110 differ in the degree of deterioration, causing the change of emission distribution (in-plane distribution) with time. Thus, when the electroluminescent element 110 deteriorates, image density unevenness occurs, causing the deterioration of image quality. Moreover, when the emission distribution (in-plane distribution) changes with time, the coefficient of correlation of light detected by the light-detecting element 120 with light actually outputted from the light-projecting region A_{LE} changes, making it impossible to detect the quantity of light to a high precision.

The tendency that the thickness of the light-emitting layer 112 becomes uneven due to interposed matters such as light-detecting element 120 becomes more remarkable with the structure having a reduced thickness of light-emitting layer. Thus, this tendency is a factor that drastically governs the performance of light head and other devices employing a light-emitting device. In particular, in the case where the light-emitting layer 112 is made of a polymer material, the light-emitting layer 112 is normally formed by a coating method and thus is more remarkably subject to ununiformity of thickness. Accordingly, in order to realize the uniformalization of emission distribution and the enhancement of durability in the light-emitting device, it is important to suppress the factor of change of thickness of the light-emitting layer 112 due to the presence of interposed matters in the laminate such as light-detecting element in the related art examples so that the thickness of the light-emitting 112 is made constant.

### SUMMARY OF THE INVENTION

The invention has been worked out in the light of the aforementioned circumstances. Therefore, an aim of the invention is to provide a light-emitting device having a reduced dispersion of thickness of light-emitting layer, a uniform emission distribution and an excellent durability.

The light-emitting device of the invention has been worked out in the light of the aforementioned aim and is a light-emitting device comprising a light-emitting element and a light-detecting element for detecting light emitted by the light-emitting element laminated on a substrate, wherein the light-emitting element has a light-projecting region provided on a flat surface thereof.

In this arrangement, the light-projecting region of the light-emitting element is provided on a flat surface, making it possible to form a light-emitting layer to a uniform thickness. Thus, a light-emitting device having a uniform emission distribution and a prolonged life can be provided.

Further, in the configuration of the light-emitting device of the invention, when the element region of the light-detecting element is formed larger than the light-projecting region of the light-emitting element and the light-projecting region of the light-emitting element is disposed inside the light-receiving region, the light-detecting element can form no level differences in the light-projecting region of the light-emitting device, giving no effect of making the thickness of the layers overlying the light-detecting element, i.e., layers formed at the steps following the formation of the light-detecting element uneven. Therefore, the light-emitting layer can be formed to a uniform thickness. Accordingly, the light-emitting layer allows electric current to flow therethrough less unevenly, making it possible to prevent the occurrence of uneven emission distribution and the reduction of life of the light-emitting device.

Moreover, the light-detecting element incorporated in the light-emitting device of the invention has a larger element region than the light-projecting region, making it assured that the light outputted from the light-emitting layer can be detected. Thus, the precision in the detection of quantity of light to be used in the correction of light can be enhanced. At the same time, the conversion of light to electric signal can be efficiently made.

In the case of a so-called bottom emission type light-emitting device which emits light at the substrate side thereof, an electroluminescent element is laminated on a light-detecting element formed on the substrate as a light-emitting element. The light emitted by the electroluminescent element passes through the light-detecting element from which it is outputted at the substrate side thereof. The quantity of light emitted is detected at the emission side, making it possible to detect the quantity of light to higher precision.

Further, in the case where the light-detecting element is composed of a thin film transistor formed at the same step as the thin film transistor (TFT) constituting the driving circuit, the resulting light-detecting element is covered by a light-transmitting electrode disposed on the substrate side of the electroluminescent element with an interlayer insulating film interposed therebetween. This light-transmitting electrode acts as a gate electrode of TFT and also acts as a gate insulating film effectively depending on the thickness of the interlayer insulating film and the dielectric constant dependent on the properties of the interlayer insulating film. The potential at the anode (light-transmitting electrode) of the electroluminescent element which is a light-emitting element causes the application of an electric field to the channel. Thus, the gate-source voltage V_{GS} causes the properties of the thin film transistor as a light-detecting element to be controlled. It is known that since this thin film transistor as a light-detecting element tends to show a great output fluctuation in the region where a photoelectric current flows, it is effective to measure the region where no electric current flows, i.e., OFF region. Therefore, by controlling the thickness of the interlayer insulating film which is a gate insulating film or the properties of the interlayer insulating film such that the potential at the anode of this electroluminescent element can act as a gate voltage of the thin film transistor as a light-detecting element, the detection of quantity of light can be made to a higher precision. In order that the potential at the anode might thus be applied effectively as a gate potential, an arrangement is more effectively made such that the anode of the electroluminescent element fully covers the channel region of the thin film transistor as a light-detecting element.

The first electrode formed on the light-detecting element side of the electroluminescent element is normally an anode formed by a light-transmitting electrode material.

### BRIEF DESCRIPTION OF THE DRAWINGS

FIG. 1 is a sectional view illustrating the configuration of a light head employing the light-emitting device according to Embodiment 1, particularly the peripheral configuration of an electroluminescent element which is a light-emitting element provided in the light head.

FIG. 2 is a plan view of the electroluminescent element according to Embodiment 1.

FIG. 3 is a circuit diagram of a light quantity detecting circuit incorporated in the light head according to Embodiment 1.

FIG. 4 is a diagram illustrating the relationship between the gate voltage Vg and the drain current ID of a light-detecting element according to Embodiment 1.

FIG. 5 is a timing chart illustrating the timing of detection of quantity of light according to Embodiment 1.

FIG. 6 is a sectional view illustrating a modification of the peripheral configuration of the electroluminescent element according to Embodiment 1.

FIG. 7 is a sectional view of a light head according to Embodiment 2 in the form of a top emission structure.

FIG. 8 is a sectional view illustrating a modification of the peripheral configuration of an electroluminescent element according to Embodiment 2.

FIG. 9 is a configurational diagram of an image forming device comprising a light-emitting device according to Embodiment 3 as a light head.

FIG. 10 is a configurational diagram illustrating the periphery of a development station in an image forming device according to Embodiment 3.

FIG. 11 is a sectional view illustrating a light-emitting device according to Embodiment 4.

FIG. 12 is a sectional view illustrating a light-emitting device according to Embodiment 5.

FIG. 13 is a configurational diagram of a display device employing a light-emitting device according to Embodiment 6.

FIG. 14 is a diagram illustrating the pixel arrangement of a display device according to Embodiment 6.

FIG. 15A is a plan view of a light-detecting element according to Embodiment 7 and FIG. 15B is a sectional view of the light-detecting element taken on the line A-A of FIG. 15A.

FIGS. 16A and 16B each are a diagram illustrating another configuration of the light-detecting element according to Embodiment 7.

FIG. 17A is a plan view of a light detecting element according to Embodiment 8 and FIG. 17B is a sectional view of the light-detecting element taken on the line B-B of FIG. 17A.

FIG. 18A is a plan view of a light-detecting element according to Embodiment 9, FIG. 18B is a sectional view of the light-detecting element taken on the line C-C of FIG. 18A and FIG. 18C is a sectional view of the light-detecting element taken on the lines D-D and E-E of FIG. 18A.

FIG. 19A is a plan view of a light-detecting element according to Embodiment 10, FIG. 19B is a sectional view of the light-detecting element taken on the line C-C of FIG. 19A and FIG. 19C is a sectional view of the light-detecting element taken on the line G-G of FIG. 19A.

FIG. 20 is a configurational diagram illustrating the configuration of a part of a light head having a light-detecting element according to Embodiment 11 in the vicinity of the light-detecting element.

FIG. 21 is a configurational diagram illustrating the configuration of a part of a light head having a light-detecting element according to Embodiment 12 in the vicinity of the light-detecting element.

FIG. 22 is a sectional view illustrating the configuration of a related art light head, particularly the peripheral configuration of a light-emitting element provided in the light head.

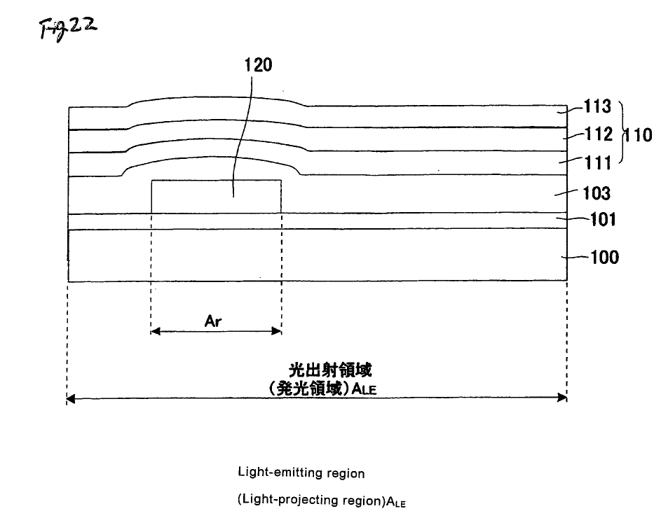

### DESCRIPTION OF THE PREFERRED EMBODIMENTS

The light-emitting device of the embodiment is a light-emitting device comprising a light-emitting element and a light-detecting element laminated on a substrate, which light-detecting element being adapted to detect the light emitted by the light-emitting element, wherein the light-projecting region of the light-emitting element is provided on a flat surface.

In this arrangement, the light-projecting region of the light-emitting element is provided on a flat surface, making it possible to form a light-emitting layer to a uniform thickness and provide a light-emitting device having a uniform emission distribution and a prolonged life.

In the embodiment, the light-detecting element and the light-emitting element are formed on the substrate in this order. The flat surface is formed by the light-detecting element.

In this arrangement, the light-projecting region of the light-emitting element is provided on a flat surface which is a part of the light-detecting element, making it possible to form the light-emitting layer to a uniform thickness and provide a light-emitting device having a uniform emission distribution and a prolonged life.

In the embodiment, the light-emitting element is formed laminated on the top of the light-detecting element formed on the substrate and the element region of the light-detecting element is formed larger than the light-projecting region so that it covers the light-projecting region of the light-emitting element.

In this arrangement, the element region of the light-detecting element resulting in the formation of a level difference is formed covering the light-projecting region of the light-emitting element, making it possible to prevent the occurrence of level difference in the light-projecting region of the light-emitting element and suppress the change of thickness of the light-emitting layer in the light-emitting device in the light-projecting region which is an effective region of the light-emitting device.

The term “element region of light-detecting element” as used herein is meant to indicate a semiconductor region constituting the light-detecting element, normally an island region of polycrystalline silicon layer. However, in the structure having a polycrystalline silicon layer integrally formed with a substrate and partly insulated by anodization or doping with oxygen ion, the active region surrounded by the insulated region is included in the element region. In this case, the active region as element region and its peripheral region are mostly present on the same plane. Therefore, even when the light-projecting region, preferably light-emitting region is partly on the nonactive region, they can be formed on a flat surface.

In the embodiment, the light-detecting element is formed by a semiconductor region formed in an island form on the substrate. The light-projecting region of the light-emitting element is formed in the island-shaped semiconductor region. The lower electrode of the light-emitting element is formed covering the semiconductor region.

Thus, in the embodiment, the light-detecting element is formed in the semiconductor island region formed on the substrate and the light-projecting region of the light-emitting element is formed in the semiconductor island region.

In this arrangement, the light-projecting region of the light-emitting element is disposed inside the outer edge of the semiconductor island region on the semiconductor island region having a light-detecting element formed therein. Thus, the light-projecting region of the light-emitting element is formed on a flat surface. Accordingly, the light-emitting device can be formed with an extremely high controllability.

Preferably, the first electrode disposed on the light-detecting element side of the light-emitting element is provided on the semiconductor island region, making it possible to eliminate level difference on the light-emitting layer.

The embodiment also concerns a light-emitting device comprising an electroluminescent element as a light-emitting element which is a light source and a light-detecting element disposed superimposed on the electroluminescent element for monitoring the light outputted from the electroluminescent element and generating an electrical signal for use in the correction of the quantity of light emitted, wherein the element region of the light-detecting element is formed larger than the light-projecting region of the electroluminescent element and the light-projecting region of the electroluminescent element in particular is arranged inside the element region of the light-detecting element.

When the area of the light-detecting element is larger than that of the light-projecting region of the electroluminescent element and the light-projecting region of the electroluminescent element is disposed inside the element region of the light-detecting element, the effect of the light-detecting element of generating ununiformity in the thickness of the light-emitting layer can be eliminated, making it possible to uniformalize the thickness of the light-projecting region of the light-emitting layer.

Accordingly, the light-emitting layer allows electric current to flow therethrough less unevenly. Thus, the light head or other devices employing the light-emitting device of the embodiment are not subject to the deterioration of image quality and the reduction of life due to uneven emission distribution.

In this structure, the lower electrode of the light-emitting element is larger than the semiconductor region constituting the light-detecting element and the semiconductor region is larger than the light-projecting region.

In other words, in the embodiment, the lower electrode of the light-emitting element, the semiconductor region constituting the light-detecting element and the light-projecting region are formed in this order of size decreasing, particularly by 1 μm or more.

By providing a margin of 1 μm or more, no level difference can occur in the light-projecting region of the light-emitting element even when uneven thickness distribution, positional deviation, size deviation or the like occurs due to the element preparation process. As a result, a light-emitting device having a high reliability can be formed more efficiently. In particular, when the rise of the size of the light-emitting device is considered, deviation due to the element preparation process, etc. increase. Thus, taking into account the related art ordinary process for the preparation of a thin film transistor on a glass substrate, the provision of a margin of 1 μm or more makes it easy to form the light-emitting device.

In the embodiment, the light-emitting element is laminated on the top of the light-detecting element formed on the substrate and the outer edge of the element region of the light-detecting element is formed outside the light-projecting region of the light-emitting element.

In this arrangement, the outer edge of the element region of the light-detecting element resulting in the formation of a level difference is formed outside the light-projecting region of the light-emitting element, making it possible to prevent the occurrence of level difference in the light-projecting region of the light-emitting element and suppress the change of thickness of the light-emitting layer in the light-emitting device in the light-projecting region which is an effective region of the light-emitting device.

In the embodiment, the light-detecting element is formed in the semiconductor layer formed integrally with the substrate. The light-projecting region of the light-emitting element is formed in the semiconductor layer. The lower electrode of the light-emitting element is formed on a part of the semiconductor layer. The light-projecting region is defined smaller than the lower electrode.

In this arrangement, the light-detecting element and the electroluminescent element are formed laminated on each other on the insulating substrate such as glass substrate. Further, the element region is formed free of edge. In other words, the element region is integrally formed. The element region is formed larger than the light-projecting region. As a result, the detection of quantity of light can be realized at an extremely high efficiency. At the same time, the reduction of size and thickness of the light-emitting device can be realized.

Even in the case where the integrally formed semiconductor layer is used, when the image defining portion is formed by a light screening film or insulating film, the light-projecting region can be formed on a flat surface. In other words, in the case where the semiconductor layer (semiconductor region) is formed larger than the light-transmitting electrode such as ITO, the light-projecting region is preferably formed free of edge of the light-transmitting electrode. In some detail, an arrangement is made such that the light-projecting region is disposed inside the outer edge of the light-transmitting electrode.

In other words, the light-projecting region, i.e., light-emitting region is defined by the image defining portion. For example, when the light-projecting region is defined by an image defining portion formed by providing an insulating film having an opening interposed between the anode and the light-emitting layer, the light-projecting region can be disposed inside the light-receiving region of the light-detecting element, making it possible to eliminate the effect of the light-detecting element of generating ununiformity in the thickness of the light-emitting layer and uniformalize the thickness of the light-projecting region of the light-emitting layer.

Accordingly, the light-emitting layer allows electric current to flow therethrough less unevenly, making it possible to prevent the occurrence of uneven emission distribution and the reduction of life of the light-emitting device.

While the foregoing has been made with reference to the case where the image defining portion is formed by the insulating film provided on at least one of the anode and the cathode so that the light-projecting region is electrically controlled, the light-projecting region may be optically controlled by a light screening film having an opening formed therein. When the lower electrode of the semiconductor layer or electroluminescent element and the image defining portion are formed taking into account the precision of positioning of these layers or the precision of product, it is necessary that the difference in size of these layers be sufficiently great. As a result, the light-projecting region cannot be occasionally formed sufficiently large. However, the use of the integrally formed semiconductor layer makes it possible to form the light-projecting region sufficiently large without taking into account the process of the semiconductor layer.

In the embodiment, the substrate is an insulating light-transmitting substrate. The light-detecting element is a semiconductor element having a semiconductor layer formed on the light-transmitting glass substrate as an active region. The light-emitting element comprises a first electrode formed by a light-transmitting electrically-conductive film formed covering the semiconductor layer, a light-emitting layer formed on the first electrode and a second electrode formed on the light-emitting layer. The light-emitting layer is allowed to emit light when an electric field is applied between the light-emitting element and the first electrode.

The aforementioned arrangement is made such that light is withdrawn at the substrate side. The light emitted by the light-emitting element is directly detected by the light-detecting element and then goes out at the light-detecting element side.

The term “insulating substrate” as used herein is meant to include a substrate the surface of which has been insulated by forming an insulating film thereon.

In the embodiment, the substrate is an insulating substrate having a reflective surface. The light-detecting element is a semiconductor element having a semiconductor layer formed on the substrate as an active region. The light-emitting element comprises a first electrode composed of a light-transmitting electrically-conductive film formed covering the semiconductor layer, a light-emitting layer formed on the first electrode and a light-transmitting second electrode formed on the light-emitting layer. In this arrangement, the light-emitting layer is allowed to emit light when an electric field is applied between the light-emitting layer and the first electrode.

In this arrangement, light is withdrawn at the side opposite the substrate as opposed to the aforementioned arrangement. The light emitted by the light-emitting element is then directly detected by the light-detecting element while being reflected by the reflective surface. The light then goes out at the light-emitting element side. In this arrangement, the light reflected by the reflective surface can be certainly detected.

In this embodiment, the semiconductor element constituting the light-emitting element is composed of a diode. The diode may be PN diode or PIN photodiode.

In this arrangement, the light emitted by the light-emitting can be detected by a simple structure.

In the embodiment, the semiconductor element constituting the light-emitting element is composed of a transistor which is formed having the first electrode of the light-emitting element as a gate electrode.

In this arrangement, the first electrode of the light-emitting element is disposed opposed to the active region of the light-detecting element with the insulating film interposed therebetween. Thus, the first electrode acts effectively as a gate electrode to control the gate-source voltage V_{GS} of the light-detecting element. Accordingly, the operating region of the light-detecting element can be controlled by controlling the potential of the gate electrode.

In the embodiment, the semiconductor element is a thin film transistor composed of a polycrystalline silicon or amorphous silicon. A first electrode is formed with the interposition of an insulating film formed covering the semiconductor layer. The thin film transistor constitutes an electric field transistor having the first electrode of the light-emitting element as a gate electrode and the insulating film as a gate insulating film. The gate insulating film is arranged so as to have a thickness that causes a voltage drop allowing the negligence of the dispersion of potential of the first electrode.

In this arrangement, a voltage drop occurs due to the thickness of the insulating film disposed interposed between the light-detecting element and the electroluminescent element, making it possible to determine V_{GS} developed by the presence of gate potential on the channel. The thickness of the gate insulating film makes it possible to determine the operating region of the light-detecting element.

In the embodiment, the light-detecting element is composed of an island-shaped polycrystalline silicon or amorphous silicon. The area of the island-shaped portion is larger than the light-projecting region.

When the area of the island-shaped light-detecting element is formed larger than the light-projecting region and the light-projecting region is disposed inside the light-detecting element, the effect of the light-emitting element of generating ununiformity in the thickness of the light-emitting layer can be eliminated, making it possible to uniformalize the thickness of the light-emitting region of the light-emitting layer. Accordingly, the light-emitting layer allows electric current to flow therethrough less unevenly, making it possible to prevent the occurrence of uneven emission distribution and the reduction of life of the light-emitting device.

Further, in the embodiment, the semiconductor element constituting the light-detecting element is formed in the same layer as the thin film transistor which is a driving circuit for the light-emitting element. The formation of the thin film transistor and the light-detecting element in the same layer using etching or the like makes it possible to simplify the process for the production of the light-emitting device and reduce the production cost. In particular, the process for the formation of the polycrystalline silicon layer on the glass substrate involves a high temperature process. In the aforementioned arrangement, however, a high reliability can be obtained with an extremely good controllability merely by one adjustment.

In the embodiment, the light-projecting region is defined by an opening formed in the insulating film provided interposed between the first electrode or the second electrode and the light-emitting layer.

In this arrangement, the light-projecting region of the electroluminescent element is determined by the light-emitting layer formed on a region disposed opposed to the first electrode and the second electrode. Accordingly, even when a region having a deteriorated film quality occurs at the end of the light-emitting layer, the first electrode or the second electrode or ununiformity in thickness, positional deviation, size deviation or the like occurs due to the element preparation process, the portion covered by the insulating film constitutes no light-projecting region, making it possible to prevent deterioration and enhance reliability.

By thus defining the light-projecting region by an image defining portion formed by providing an insulating film having an opening interposed between the anode and the light-emitting layer, the light-projecting region can be disposed inside the light-receiving region of the light-detecting element, making it possible to eliminate the effect of the light-detecting element of generating ununiformity in the thickness of the light-emitting layer and uniformalize the thickness of the light-projecting region of the light-emitting layer. Accordingly, the light-emitting layer allows electric current to flow therethrough less unevenly, making it possible to prevent the occurrence of uneven emission distribution and the reduction of life of the light-emitting device. By thus forming the image defining portion by an insulating film provided on at least one of the anode and the cathode, the light-projecting region can be electrically controlled.

Further, in the embodiment, the light-projecting region is defined by an opening formed in a light screening film provided closer to the light emission side than the light-projecting region of the light-emitting element.

In this arrangement, the light-projecting region is determined by the opening formed in the light screening film. Accordingly, even when a region having a deteriorated film quality occurs at the end of the light-emitting layer or ununiformity in thickness, positional deviation, size deviation or the like occurs due to the element preparation process, the portion covered by the light screening film constitutes no light-projecting region, making it possible to prevent deterioration and enhance reliability. In this case, however, the light-emitting region occurs on a level difference and thus can deteriorate early. However, since the detection of quantity of light can be effected to a high precision, high precision correction can continue long.

In a specific embodiment of definition of the light-emitting region, the aforementioned light screening portion having an opening may be formed as an image defining portion instead of insulating film having an opening interposed between the electrode and the light-emitting layer.

The term “light-projecting region” as used herein is meant to a region at which light is projected from by the light-emitting device. In the case where no light screening portion having an opening is formed, the term “light-projecting region” indicates the light-emitting region itself. In the case where a light screening portion having an opening is formed as an image defining portion, the term “light-projecting region” indicates the region corresponding to the opening.

Further, in the embodiment, one light-detecting element is provided every one light-projecting region.

The light-emitting device comprises a plurality of light-projecting regions aligned in a line. By disposing one light-detecting element every one light-projecting region, the light components outputted from the plurality of light-projecting regions can be independently measured at the same time, making it possible to measure the quantity of light emitted by the entire light-emitting device at a high speed.

Moreover, in the embodiment, the light-emitting element is an organic electroluminescent element comprising an organic semiconductor layer as a light-emitting layer or an inorganic electroluminescent element comprising an inorganic semiconductor layer as a light-emitting layer.

An organic electroluminescent element can give a high brightness at a low power and thus can provide a light-emitting device which is excellent from the standpoint of power consumption.

An inorganic electroluminescent element comprises a light-emitting layer composed of an inorganic material and thus is excellent in stability. The inorganic electroluminescent element can be produced by a screen printing method or the like that causes the production of little defects and requires no facilities such as clean room. Thus, the inorganic electroluminescent element can be produced at a high productivity. Accordingly, the inorganic electroluminescent element can provide a light-emitting device at reduced product cost.

Further, in the embodiment, a light quantity correcting portion for correcting the quantity of light emitted by the light-emitting element on the basis of the output of the light-detecting element is provided.

When a light-detecting element adapted to correct the quantity of light is thus provided, an electric signal suitable for the correction of the quantity of light can be fed back from the light-detecting element to the light-emitting element, making it possible to control appropriately the quantity of light emitted by the light-emitting element in the light-emitting device.

Since the light-detecting element to be incorporated in the light-emitting device of the embodiment has a larger element region than the light-projecting region of the light-emitting element, the light outputted from the light-emitting layer can be efficiently collected and converted to an electric signal for correction.

As previously mentioned, the area of the light-detecting element comprising an island-shaped polycrystalline silicon layer as a light-detecting region to be incorporated in the light-emitting device of the embodiment is larger than the light-projecting region (light-emitting region), making it possible to convert efficiently the light outputted from the light-emitting layer to an electric signal for use in the correction of the quantity of light emitted by the light-emitting element.

Moreover, in the embodiment, a light quantity correcting portion for correcting the emission time of the light-emitting element on the basis of the output of the light-detecting element is provided. When a light-detecting element adapted to correct the emission time of the light-emitting element is thus provided, an electric signal suitable for the correction of emission time can be fed back from the light-detecting element to the light-emitting element, making it possible to control appropriately the emission time.

Further, in the embodiment, the light-detecting element is composed of a photoconductor and a good conductor disposed adjacent to a plurality of sides of the photoconductor. The junction of the photoconductor with the good conductor has a larger area than the section of the photoconductor taken on the line parallel to the good conductor. In this arrangement, the electrical resistance of the photoconductor can be reduced, making it possible to suppress heat noise of light detection signal.

Moreover, in the embodiment, the junction is formed by a surface oblique to the width direction, length direction or thickness direction. In this arrangement, the electrical resistance of the photoconductor can be reduced, making it possible to suppress heat noise of light detection signal.

Further, in the embodiment, the aforementioned oblique surface is formed by a curved surface. In this arrangement, the electrical resistance of the photoconductor can be reduced, making it possible to suppress heat noise of light detection signal.

The method for the production of the light-emitting device of the embodiment comprises the following steps.

i) A step of forming a light-detecting element having an island-shaped semiconductor region on a substrate; and

ii) A step of forming a light-emitting element superimposed on the semiconductor region on the top of a flat portion of the semiconductor region, wherein the step ii) comprises the following steps:
a) A step of forming a driving electrode of the light-emitting element covering the entire part of the island-shaped semiconductor region;
b) A step of covering a part of the driving electrode by an insulating film and forming an opening at least inside the flat portion to define a light-emitting region;
c) A step of spreading a luminescent material over a portion including at least the opening to form a light-emitting layer; and
d) A step of forming other electrode made of a metal as a main material on the spread of the luminescent material such that the light-emitting layer is interposed between the other electrode and the driving electrode to form the light-emitting element.

In this manner, even when the light-emitting element and the light-detecting element are formed superimposed on each other, the thickness of the light-emitting layer can be made uniform, making it possible to produce a light-emitting device having a uniform emission distribution and a prolonged life.

In the case where the light-emitting layer constituting the light-emitting element is formed by spreading a luminescent material, i.e., wet method, a more uniform light-emitting layer can be formed particularly on the flat surface. In the case of wet method in particular, the film is formed depending on the properties of the material itself, e.g., wettability and viscosity of the light-emitting layer to be spread. Therefore, when the light-emitting layer is formed on a rough surface, the thickness of the film varies. However, when the light-emitting layer is spread over a flat surface, the light-emitting layer can be formed by a simple method without using any vacuum device.

The light-emitting devices of the embodiment include a display device such as display comprising a light-detecting element disposed laminated on a light-emitting element.

The light-emitting devices of the embodiment include a light head for image forming device comprising a light-detecting element disposed laminated on a light-emitting element.

Further, an image forming device comprising as an exposure device a light head employing a light-emitting device of the embodiment is provided.

In this image forming device, the distribution of emission from the light-emitting elements each constituting a pixel is uniform. Further, these light-emitting elements have a prolonged life. Thus, the image forming device is excellent in image quality and durability. The light head employing the embodiment can be reduced in size and thus can contribute to the reduction of size of image forming device.

### EMBODIMENTS

Embodiments of implementation of the embodiment will be described in connection with the attached drawings.

Embodiments 1 and 2 will be described focusing on a light head employing a light-emitting device according to the invention.

In Embodiment 3, an example of image forming device having a light head employing the light-emitting device according to the invention incorporated therein will be described in detail.

In Embodiments 4 and 5, examples of the configuration of a light-detecting element will be described.

In Embodiment 6, a display device employing the light-emitting device according to the invention will be described.

In Embodiments 7 to 11, the configuration of a light-detecting element will be described in detail.

### Embodiment 1

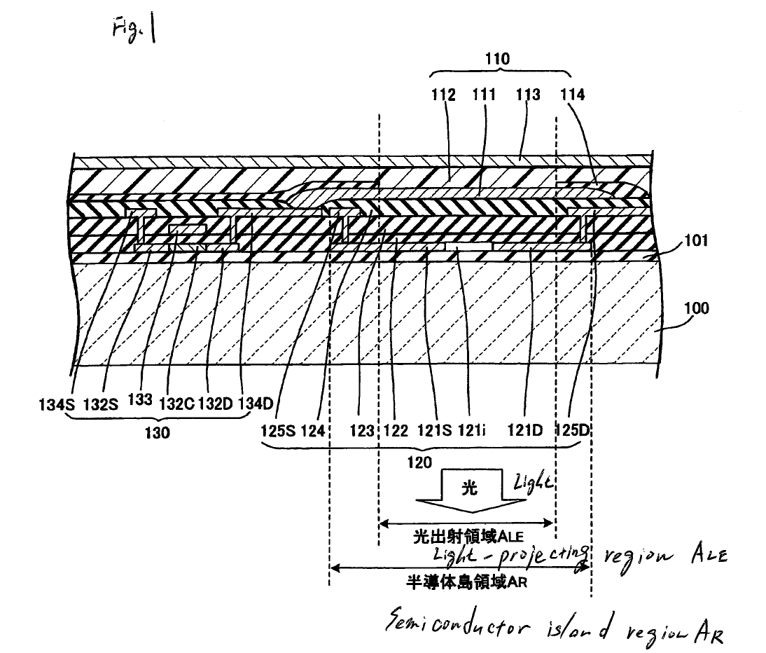

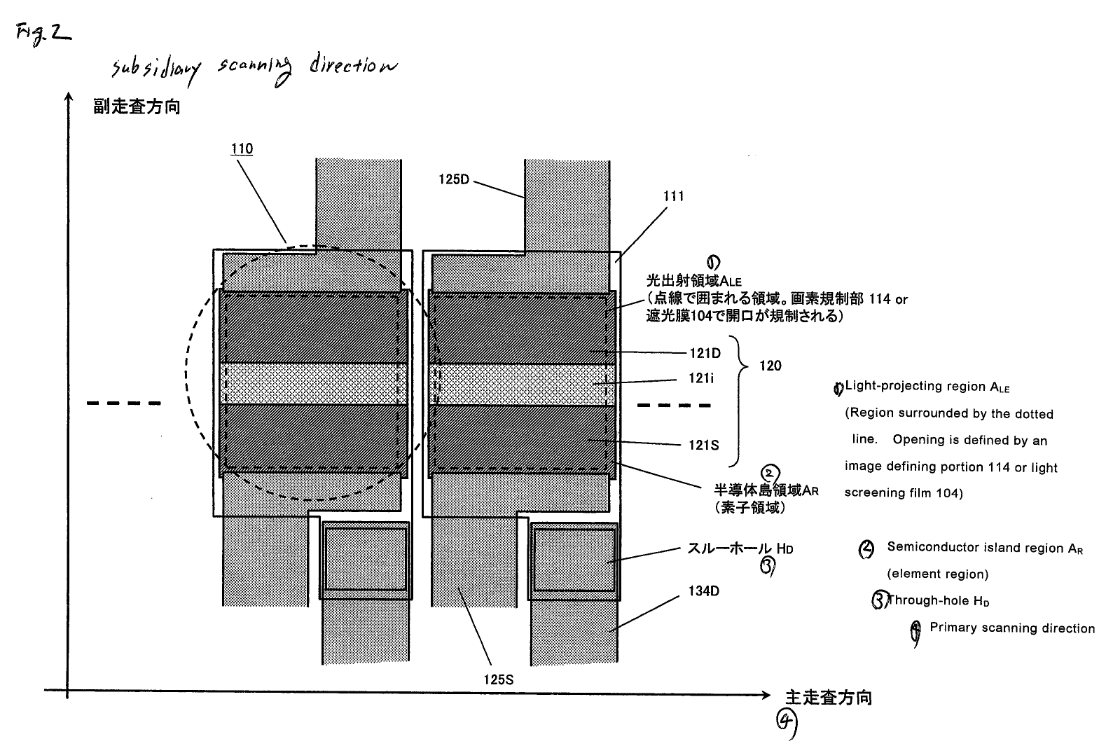

FIG. 1 is a sectional view illustrating the configuration of a light head employing the light-emitting device according to Embodiment 1, particularly the peripheral configuration of an electroluminescent element which is a light-emitting element provided in the light head. FIG. 2 is a plan view of the electroluminescent element according to Embodiment 1.

The disposition of the light-emitting element and light-detecting element according to the invention will be described in detail in connection with FIGS. 1 and 2.

FIG. 1 depicts the vertical positional relationship of the various layers constituting the electroluminescent element 110 which is a light-emitting element and the light-detecting element 120. In the light head, the electroluminescent element 110 is laminated on the top of a thin film transistor (TFT) constituting the light-detecting element 120 formed on the glass substrate 100 and the outer edge of a semiconductor island region made of a polycrystalline silicon constituting the element region of the light-detecting element 120 (The term “semiconductor island region made of a polycrystalline silicon constituting the element region of the light-detecting element 120” will be hereinafter simply referred to as “semiconductor island region A_{R}”. The semiconductor island region A_{R} may be made of an amorphous silicon.) is disposed outside the light-projecting region A_{LE} of the electroluminescent element 110 as shown in FIG. 1.

Thus, the semiconductor island region A_{R} of the light-detecting element 120 resulting in the production of level difference, i.e., the outer edge of the semiconductor island region A_{R} is formed outside the light-projecting region A_{LE} of the electroluminescent element 110. As shown, the ground of the light-emitting layer 112 constitutes a flat surface. Thus, the region corresponding to the light-projecting region A_{LE} of the electroluminescent element 110 has no level difference. Accordingly, the light-projecting region A_{LE} which is an effective region of light head has a light-emitting layer 112 formed uniformly thereon.

In other words, the light-emitting device according to Embodiment 1 has an electroluminescent element 110 as a light-emitting element and a light-detecting element 120 disposed laminated on a substrate (glass substrate 100), which light-detecting element being adapted to detect the light emitted by the light-emitting element. The light-projecting region A_{LE} of the light-emitting element is provided on the flat surface.

Further, in the light-emitting device according to Embodiment 1, the light-detecting element 120 and the electroluminescent element 110 as a light-emitting element are formed on the substrate (glass substrate 100) in this order, and the flat surface is composed of the light-detecting element 120.

Moreover, in the light-emitting device according to Embodiment 1, the electroluminescent element 110 which is a light-emitting element is formed laminated on the top of the light-detecting element 120 formed on the substrate (glass substrate 100) and the element region of the light-detecting element 120 (i.e., semiconductor island region A_{R}) is formed larger than the light-projecting region A_{LE} so as to cover the light-projecting region A_{LE} of the light-emitting element 110.

From a different standpoint of view, it can be said that the light-emitting element 110 is formed on the top of the light-detecting element 120 formed on the substrate (glass substrate 100) and the outer edge of the element region of the light-detecting element 120 (i.e., semiconductor island region A_{R}) is formed disposed outside the light-projecting region A_{LE} of the light-emitting element 110.

The light head according to the present embodiment comprises a light-detecting element 120 and an electroluminescent element 110 as a light-emitting element laminated sequentially on a glass substrate 100 having a base coat layer 101 formed thereon for leveling, a driving transistor 130 composed of a thin film transistor for driving the electroluminescent element 110 while correcting the driving current or driving time depending on the output of the light-detecting element 120 and a driving circuit (not shown) as a chip IC connected to the driving transistor 130 as shown in FIG. 1.

In the light-detecting element 120, a source region 121S and a drain region 121D are formed by doping the semiconductor island region A_{R} made of a polycrystalline silicon layer formed on the base coat layer 101 in a high concentration with a channel region 121i made of a band-like i layer interposed therebetween. A source electrode 125S and a drain electrode 125D are formed extending through through-holes piercing a first insulating film 122 and a second insulating film 123 made of a silicon oxide film formed on the source region 121S and the drain region 121D. An electroluminescent element 110 is formed on the top of the source electrode 125S and the drain electrode 125D with a silicon nitride film interposed therebetween as a protective film 124. ITO (indium tin oxide) of an anode 111 as a first electrode, an image defining portion 114 which is an insulating film for covering a part of the anode to define an opening, a light-emitting layer 112 and a cathode 113 as a second electrode are formed laminated in this order. In this configuration, the light-projecting region A_{LE} is defined by the image defining portion 114 which is an insulating film.

As can be seen in the drawings, the light-detecting element 120 is formed in an island-shaped semiconductor region (i.e., semiconductor island region A_{R}) formed on the substrate 100, the light-projecting region A_{LE} of the light-emitting element 110 is disposed inside the semiconductor island region A_{R}, and the lower electrode (anode 111) of the light-emitting element 110 is formed covering the semiconductor island region A_{R}.

In this configuration, the light-projecting region A_{LE} is defined by the opening formed in the insulating film (image defining portion 114) provided interposed between the first electrode (anode 111) and the light-emitting layer 112. The image defining portion 114 may be provided interposed between the second electrode (cathode 113) and the light-emitting layer 112 to define an opening.

On the other hand, the various layers constituting the light-detecting element 120 are formed in the same layer at the same production step as the driving transistor 130 composed of a thin film transistor. In some detail, the source region 132S and the drain region 132D are formed at the same step as the semiconductor island region A_{R} of the light-detecting element 120 with the channel region 132C of the driving transistor 130 interposed therebetween. The source electrode 134S, the drain electrode 134D and the gate electrode 133 in contact with these regions constitute the driving transistor 130.

On the other hand, the light-detecting element 120 can be regarded as constituting a thin film transistor (electric field transistor) having the first electrode (anode 111) of the light-emitting element as a gate electrode and the first insulating film 122, etc. as gate insulating film. However, the total thickness of the first insulating film 122, the second insulating film 123 and the protective film 124 reaches several times to scores of times that of the gate insulating film of ordinary thin film transistor. Therefore, even if the first electrode (anode 111) is regarded as gate electrode, it can be regarded as a thickness that causes a voltage drop allowing the negligence of the dispersion of potential at these electrodes.

These layers are formed by an ordinary semiconductor process comprising the formation of thin semiconductor film by CVD method, sputtering method or vacuum metallizing method, polycrystallization by annealing, patterning by photolithography, etching, injection of impurity ions, formation of insulating film/metallic film, etc.

In this configuration, the glass substrate 100 is a colorless transparent glass sheet. As the glass substrate 100 there may be used an inorganic oxide glass such as transparent or semi-transparent soda lime glass, barium-strontium-containing glass, lead glass, aluminosilicate glass, borosilicate glass, barium borosilicate glass and quartz glass or an inorganic glass such as inorganic fluoride glass. In general, in the case where a thin film transistor is formed on the surface of the glass substrate 100, borosilicate glass such as #1737 produced by Corning Inc. is often used.

Other materials may be employed as substitute for glass substrate 100. For example, a polymer film made of a polymer material such as transparent or semi-transparent polyethylene terephthalate, polycarbonate, polymethyl methacrylate, polyether sulfon, polyvinyl fluoride, polypropylene, polyethylene, polyacrylate, amorphous polyolefin, fluororesin polyisiloxane and polysilane may be used. Alternatively, chalcogenoid glass such as transparent or semi-transparent As₂S₃, As₄₀S₁₀ and S₄₀Ge₁₀ or metal oxide or nitride such as ZnO, Nb₂O, Ta₂O₅, SiO, Si₃N₄, HfO₂ and TiO₂ may be used. Alternatively, in the case where the light emitted by the light-emitting region is withdrawn without passing through the substrate, a semiconductor material such as opaque silicon, germanium, silicon carbide, gallium arsenic and gallium nitride may be used. Alternatively, the substrate may be properly selected from the group consisting of the aforementioned transparent substrate materials containing pigment or the like and surface-insulated metallic materials. A laminated substrate having a plurality of substrate materials laminated on each other may be used. Alternatively, a substrate formed by forming an insulating film made of an inorganic insulating material such as SiO₂ and SiN or an organic insulating material such as resin coating an electrically-conductive substrate made of a metal such as Fe, Al, Cu, Ni, Cr or alloy thereof to insulate the surface thereof may be used.

A circuit made of resistor, capacitor, inductor, diode, transistor or the like for driving the electroluminescent element 110 may be formed integrated on the surface or the interior of the substrate such as glass substrate 100 as described later.

Depending on the purpose, a material that transmits only light having a specific wavelength or a light-light converting material capable of converting into light having a specific wavelength may be used. The substrate is preferably insulating but is not specifically limited to insulating properties. The substrate may have electrical conductivity so far as the driving of the electroluminescent element 110 cannot be impaired or depending on the purpose.

The base coat layer 101 may be composed of a first layer made of, e.g., SiN and a second layer made of, e.g., SiO₂. The SiN layer and the SiO₂ layer may be formed also by vacuum metallizing method or the like but is preferably formed by a sputtering method or CVD method.

On the base coat layer 101 are formed the driving transistor 130 for the electroluminescent element 110 and the light-detecting element 120 from a polycrystalline silicon layer formed at the same step. The driving circuit for the electroluminescent element 110 is composed of circuit elements such as resistor, capacitor, inductor, diode and transistor, a wiring for electrically connecting these circuit elements and contact holes (through-holes). Taking into account the miniaturization of the light head, however, a thin film transistor is preferably used. In Embodiment 1, the light-detecting element 120 is disposed in between the electroluminescent element 110 containing the light-emitting layer 112 and the glass substrate 100 from which light is emitted and the semiconductor island region A_{R} of the light-detecting element 120 has a larger area than the light-projecting region A_{LE} as can be seen in FIG. 1.

As can be seen in FIG. 2, the light-projecting region A_{LE} is present inside the light-detecting element 120 as the electroluminescent element 110 is viewed from the top. Therefore, any material that doesn't transmit light cannot be used to form the light-detecting element 120. Accordingly, in order that the light emitted by the light-emitting layer 112 might not go out of the glass substrate 100, the light-detecting element 120 must be formed by a light-transmitting material. As the transparent material of the light-detecting element 120 there is preferably used, e.g., a polycrystalline silicon.

In Embodiment 1, after the formation of the uniform semiconductor layer on the base coat layer 101, the semiconductor layer is then subjected to etching so that the driving transistor 130 and the light-detecting element 120 are formed from the same layer. The process for forming the island-shaped independent driving transistor 130 and the light-detecting element 120 from the same semiconductor layer at once is advantageous in the reduction of the number of production steps required and the production cost. In the light-detecting element 120, the semiconductor island region A_{R} which receives the light outputted in the light-projecting region A_{LE} is the surface of island-shaped polycrystalline silicon or amorphous silicon which acts as light-detecting element 120.

On the driving transistor 130 for applying an electric field to the light-emitting layer 112 of the electroluminescent element 110 and the light-detecting element 120 are formed the first insulating film 122, second insulating film 123 and protective film 124 made of, e.g., silicon oxide film. For the light-detecting element 120, these insulating films and protective film 124 each act as a gate insulating film for the anode 111 which is regarded as a gate electrode. The voltage drop due to the thickness of these layers causes the determination of the width of drop from the potential of the anode 111. The first insulating film 122, the second insulating film 123 and the protective film 124 constituting the gate insulating film are formed by vacuum metallizing method, sputtering method, CVD method or the like.

On the surface of the first insulating film 122 disposed directly above the driving transistor 130 as a gate insulating film is formed a gate electrode 133. As the material of the gate electrode 133 there is used, e.g., a metallic material such as Cr and Al. Alternatively, in the case where the gate electrode 133 needs to be transparent, ITO or a laminate of ITO and thin metal film may be used. The gate electrode 133 is formed by vacuum metallizing method, sputtering method, CVD method or the like.

On the surface of the substrate having the gate electrode 133 formed thereon is formed the second insulating film 123. The second insulating film 123 is formed extending over the entire surface of the laminate which has been formed so far. The second insulating film 123 is made of, e.g., SiN and is formed by vacuum metallizing method, sputtering method, CVD method or the like.

On the second insulating film 123 are formed the drain electrode 125D as a light-detecting element output electrode, the source electrode 125S as a light-detecting element grounding electrode and the source electrode 134S and the drain electrode 134D of the driving transistor 130. The drain electrode 125D as a light-detecting element output electrode and the source electrode 125S as a light-detecting element grounding electrode are connected to the source region 121S and the drain source 121D of the light-detecting element 120, respectively, to transmit the electric signal outputted from the light-detecting element 120 and ground the light-detecting element 120. On the other hand, the source electrode 134S and the drain electrode 134D are connected to the source region 132S and the drain source 132D of the driving transistor 130, respectively. In this arrangement, when a predetermined potential is applied to the gate electrode 133 with a predetermined potential difference being applied between the source electrode 134S and the drain electrode 134D, an electric field is applied to the channel region 132C to render the driving transistor 130 capable of acting as a switching element that operates as a circuit for driving the electroluminescent element 110 as a light-emitting element.

As the material of the drain electrode 125D as a light-detecting element output electrode, the source electrode 125S as a light-detecting element grounding electrode and the source electrode 134S and the drain electrode 134D of the driving transistor 130 there is used a metal such as Cr and Al. Alternatively, in the case where these electrodes need to be transparent, ITO or a laminate of ITO and thin metal film may be used.

As shown in FIG. 1, the drain electrode 125D as a light-detecting element output electrode and the light-detecting element grounding electrode extend through the first insulating film 122 and the second insulating film 123 and are electrically connected to the light-detecting element 120. On the other hand, the source electrode 134S and the drain electrode 134D extend through the first insulating film 122 and the second insulating film 123 and are electrically connected to the driving transistor 130. Accordingly, prior to the formation of the drain electrode 125D as a light-detecting element output electrode, the source electrode 125S as a light-detecting element grounding electrode and the source electrode 134S and the drain electrode 134D of the driving transistor 130, it is necessary that through-holes be formed in the first insulating film 122 and the second insulating film 123 for connecting the drain electrode 125D as a light-detecting element output electrode and the source electrode 125S as a light-detecting element grounding electrode to the light-detecting element 120 and for connecting the source electrode 134S and the drain electrode 134D to the driving transistor 130.

These through-holes each have a thickness great enough to expose the surface of the light-detecting element 120 and the surface of the driving transistor 130, i.e., contact surface of the light-detecting element 120 with the drain electrode 125D and the source electrode 125S and contact surface of the driving transistor 130 with the source electrode 134S and the drain electrode 134D. These through-holes are formed by subjecting the insulating films to etching or the like directly above the end of the light-detecting element 120 and the driving transistor 130. The etching of these insulating films is effected with a halogen-based etching gas. The first insulating film 122 and the second insulating film 123 are patterned with an etching gas with the surface thereof being masked by a resist pattern having an opening formed by photolithography to form through-holes therein. As the etching gas to be used during this patterning there is used one causing no chemical reaction with the material constituting the light-detecting element 120 and the driving transistor 130.

After the termination of exposure of the contact surface of the drain electrode 125D as a light-detecting element output electrode and the source electrode 125S as a light-detecting element grounding electrode with the light-detecting element 120 and the contact surface of the source electrode 134S and the drain electrode 134D with the driving transistor 130, the drain electrode 125D as a light-detecting element output electrode, the source electrode 125S as a light-detecting element grounding electrode and the source electrode 134S and the drain electrode 134D of the driving transistor 130 are then formed. The source electrode 134S and the drain electrode 134D are obtained by forming a metal layer as a sensor electrode uniformly on the surface of the second insulating film 123, the surface of the aforementioned through-holes, the surface of the both sensor electrodes, the surface of the light-detecting element 120 and the contact surface of the driving transistor 130, and then etching the metal layer so that it is divided into a drain electrode 125D as a light-detecting element output electrode, a source electrode 125S as a light-detecting element grounding electrode, a source electrode 134S and a drain electrode 134D.

The formation of the drain electrode 125D as a light-detecting element output electrode, the source electrode 125S as a light-detecting element grounding electrode, the source electrode 134S and the drain electrode 134D is followed by the formation of the protective film 124. The protective film 124 is made of, e.g., SiN and is formed by vacuum metallizing method, sputtering method, CVD method or the like.

On the protective film 124 is formed the anode 111. The anode 111 is made of, e.g., ITO (indium tin oxide). As the material constituting the anode 111 there may be used IZO (zinc-doped indium oxide), ATO (Sb-doped SnO₂), AZO (Al-doped ZnO), ZnO, SnO₂, In₂O₃ or the like besides ITO. The anode 111 is formed on the surface of the protective film 124 directly above the light-detecting element 120 as shown in FIG. 1.

As definitely shown in FIGS. 1 and 2, the anode 111 is formed on the top of the light-detecting element 120 formed by the semiconductor island region A_{R} formed on the glass substrate 100 with the first insulating film 122 and the second insulating film 123 interposed therebetween. The size of the anode 111 is predetermined larger than the light-detecting element 120 and the light-detecting element 120 is arranged disposed inside the outer edge of the anode 111.

As shown in FIG. 1, the anode 111 is formed extending through the protective film 124 and is electrically connected to the drain electrode 134D of the driving transistor 130. Accordingly, prior to the formation of the anode 111, it is necessary that a through-hole be formed in the protective film 124 for connecting the anode 111 to the drain electrode 134D. This through-hole has a depth great enough to expose the surface of the drain electrode 134D, i.e., contact surface of the drain electrode 134D with the anode 111. This through-hole is formed by subjecting the protective film 124 to etching or the like directly above the end of the drain electrode 134D. This etching is followed by the formation of the anode 111. The anode 111 can be formed by vacuum metallizing method or the like. However, in order to obtain a dense anode 111 having a good resistance and transmittance, sputtering method or CVD method is preferably employed. In Embodiment 1, as the anode 111 there is used ITO.

After the termination of the formation of the anode 111, the image defining portion 114 is formed by an inorganic insulating material such as silicon nitride, silicon oxide, silicon oxonitride, titanium oxide, aluminum nitride and aluminum oxide or an organic insulating material such as polyimide and polyethylene. As the material of the image defining portion 114 there is preferably used one having high insulating properties as mentioned above, a strong resistance to dielectric breakdown, good film-forming properties and a good patternability. The image defining portion 114 is a member for defining the light-projecting region. The light-projecting region is defined by an opening formed in the insulating film provided interposed between the first electrode or second electrode and the light-emitting layer.

In Embodiment 1, as the materials constituting the silicon nitride film as image defining portion 114 there are used silicon nitride and aluminum nitride. The image defining portion 114 is provided interposed between the light-emitting layer 112 described layer and the anode 111 and insulates the light-emitting layer 112 disposed outside the light-projecting region A_{LE} from the anode 111 to define the light-emitting area of the light-emitting layer 112. Accordingly, the region of the light-emitting layer 112 superimposed on the image defining portion 114 is a non-light-emitting region and the region of the light-emitting layer 112 which is not superimposed on the image defining portion 114 is the light-projecting region A_{LE}. The image defining portion 114 defines the light-emitting layer 112 such that the light-projecting region A_{LE} of the light-emitting layer 112 has a smaller area than the semiconductor island region A_{R} of the light-detecting element 120 and is arranged such that the light-projecting region A_{LE} is disposed inside the semiconductor island region A_{R} of the light-detecting element 120.

The formation of the image defining portion 114 is followed by the formation of the light-emitting layer 112. The light-emitting layer 112 is formed by an inorganic luminescent material or a polymer-based or low molecular organic luminescent material described in detail hereinafter. As the inorganic luminescent material constituting the light-emitting layer 112 there may be used titanium potassium phosphate, barium boron oxide, lithium boron oxide or the like.

As the polymer-based organic luminescent material constituting the light-emitting layer 112 there is preferably used one having fluorescence or phosphorescence in the visible light range and good film-forming properties such as polymer luminescent material made of polyparaphenylene vinylene (PPV), polyfluorene and derivative thereof.

As the polymer-based light-emitting layer 112 there may be used an organic compound having a tree-like multibranched structure such as dendrimer. This organic compound has a tree-like multibranched polymer structure or tree-like multibranched low molecular structure having a luminescent structural unit wrapped three-dimensionally by a plurality of external structural units. Therefore, the luminescent structural unit is kept three-dimensionally isolated. As a result, the organic compound itself is in a particulate form. Thus, when formed into a thin film, an aggregate of these organic compounds can have adjacent luminescent structural units kept apart from each other by the presence of external structural units. In this arrangement, the luminescent structural units can be uniformly distributed in the thin film, making it possible to maintain luminescence at a high intensity over an extended period of time.

Examples of the low molecular organic luminescent materials constituting the light-emitting layer 112 include Alq₃ and Be-benzoquinolinol (BeBq₂). Other examples of the low molecular organic luminescent materials include benzooxazole-based materials such as 2,5-bis(5,7-di-t-pentyl-2-benzooxazolyl)-1,3,4-thiadiazole, 4,4′-bis(5,7-pentyl-2-benzooxazolyl)stilbene, 4,4′-bis[5,7-di-(2-methyl-2-butyl)-2-benzooxazolyl]stilbene, 2,5-bis[5,7-di-t-pentyl-2-benzooxazolyl]thiophene, 2,5-bis([5-α, α-dimethyl benzyl]-2-benzo oxazolyl)thiophene, 2,5-bis[5,7-di-(2-methyl-2-butyl)-2-benzooxazolyl]-3,4-diphenyl thiophene, 2,5-bis(5-methyl-2-benzooxazolyl) thiophene, 4,4′-bis(2-benzooxazolyl)biphenyl, 5-methyl-2-[2-[4-(5-methyl-2-benzooxazolyl)phenyl]vinyl]benzooxazolyl and 2-[2-(4-chlorophenyl)vinyl]naphtho[1,2-d]benzooxazolyl, benzothiazole-based materials such as 2,2′-(p-phenylenedivinylene)-bisbenzothiazole, benzoimidazole-based fluorescent brightening agents such as 2-[2-[4-(2-benzoimidazolyl)phenyl]vinyl]benzoimidazole and 2-[2-(4-carboxyphenyl)vinyl]benzoimidazole, 8-hydroxylquinoline-based metal complexes such as tris(8-quinolyl)aluminum, bis(8-quinolyl)magnesium, bis(benzo[f]-8-quinolyl)zinc, bis(2-methyl-8-quinolylato)aluminum oxide, tris(8-quinolyl)indium, tris(5-methyl-8-quinolyl)aluminum, 8-quinolyl lithium, tris(5-chloro-8-quinolyl)gallium, bis(5-chloro-8-quinolyl)calcium and poly[zinc-bis(8-hydroxy-5-quinolinonyl)methane], metal-chelated oxinoid compounds such as dilithium epindridione, styrylbenzene-based compounds such as 1,4-bis(2-methylstyryl)benzene, 1,4-(3-methylstyryl)benzene, 1,4-bis(4-methylstyryl)benzene, distyrylbenzene, 1,4-bis(2-ethylstyryl)benzene, 1,4-bis(3-ethylstyryl) benzene and 1,4-bis(2-methylstyryl)2-methylbenzene, distilpyrazine derivatives such as 2,5-bis(4-methyl styryl)pyrazine, 2,5-bis(4-ethylstyryl)pyrazine, 2,5-bis[2-(1-naphthyl)vinyl]pyrazine, 2,5-bis(4-methoxy styryl)pyrazine, 2,5-bis[2-(4-biphenyl)vinyl]pyrazine and 2,5-bis[2-(1-pyrenyl)vinyl]pyrazine, naphthalimide derivatives, perylene derivatives, oxadiazole derivatives, aldazine derivatives, cyclopentadiene derivatives, styrylamine derivatives, coumarine derivatives, and aromatic dimethylidene derivatives. Further examples of the low molecular organic luminescent materials include anthracene, salicylates, pyrene, and coronene. Still further examples of the low molecular organic luminescent materials include phospholuminescent materials such as fac-tris(2-phenylpyridine)indium.

The light-emitting layer 112 made of a polymer material or low molecular material is obtained by spreading a solution of the material in a solvent such as toluene and xylene by a wet film-forming method such as spin coating method, ink jet method, gap coating method and printing method to form a layer, and then allowing the solvent in the solution to evaporate. The light-emitting layer 112 made of a low molecular material is normally obtained by laminating the material on the substrate by a vacuum metallizing method, vapor deposition polymerization method or CVD method. Any of these methods may be employed depending on the characteristics of the luminescent material used.

While Embodiment 1 has been described with reference to the case where the light-emitting layer 112 is a single layer for convenience, the light-emitting layer 112 may have a three-layer structure consisting of hole-transporting layer, electron-blocking layer and the aforementioned organic luminescent material layer (all not shown) in this order as viewed from the anode 111, a two-layer structure consisting of electron-transporting layer and organic luminescent layer (both not shown) in this order as viewed from the cathode 113, a two-layer structure consisting of hole-transporting layer and organic luminescent layer (both not shown) in this order as viewed from the anode 111 or a seven-layer structure consisting of hole-injecting layer, hole-transporting layer, electron-blocking layer, organic luminescent layer, hole blocking layer, electron-transporting layer and electron-injecting layer (all not shown) in this order as viewed from the cathode 113. Alternatively, the light-emitting layer may have a simpler structure consisting of the organic luminescent material alone. Alternatively, the light-emitting layer 112 may be a mixed layer comprising materials having various functions in admixture or may have a structure having such mixed layers laminated on each other. Thus, when the light-emitting layer 112 is referred in Embodiment 1, the light-emitting layer 112 may have a multi-layer structure having functional layers such as hole-transporting layer, electron-blocking layer and electron-transporting layer. This can apply also to other embodiments described later.

As the hole-transporting layer to be used as one of the aforementioned functional layers there is preferably used one formed by a transparent material having a high hole mobility and good film forming properties such as TPD. Other examples of the hole-transporting materials employable herein include organic materials such as porphyrin compound, e.g., porphyrin, tetraphenylporphyrin copper, phthalocyanine, copper phthalocyanine, titanium phthalocyanine oxide, aromatic tertiary amine, e.g. 1,1-bis{4-(di-P-tollylamino)phenyl}cyclohexane, 4,4′,4′-trimethyl triphenylamine, N,N, N′,N′-tetrakis(P-tollyl)-P— phenylenediamine, 1-(N,N-di-P-tollylamino) naphthalene, 4,4′-bis(dimethylamino)-2-2′-dimethyl triphenylmethane, N,N,N′,N′-tetraphenyl-4,4′-diamino biphenyl, N,N′-diphenyl-N,N′-di-m-tollyl-4,4′-diaminobiphenyl, N-phenylcarbazole, stilbene compound, e.g., 4-di-P-tollylaminostilbene, 4-(di-P-tollyl amino)-4′-[4-(di-P-tollylamino)styryl]stilbene, triazole derivative, oxadiazole derivative, imidazole derivative, polyarylalkane derivative, pyrazoline derivative, pyrazolone derivative, phenylenediamine derivative, anylamine derivative, amino-substituted chalcone derivative, oxazole derivative, styrylanthracene derivative, fluorenone derivative, hydrazone derivative, silazalane derivative, polysilane-based aniline copolymer, polymer oligomer, styrylamine compound, aromatic dimethylidene-based compound and polythiophene derivative, e.g., poly-3,4-ethylenedioxythiophene (PEDOT), tetradihexylfluorenyl biphenyl (TFB) and poly-3-methylthiophene (PMeT). Alternatively, a polymer dispersion-based hole-transporting layer having a low molecular organic material for hole-transporting layer dispersed in a polymer such as polycarbonate may be used.

Further, inorganic oxides such as MoO₃, V₂O₅, WO₃, TiO₂, SiO and MgO may be used. When as the hole-transporting layer there is used a transition metal oxide such as MoO₃, V₂O₅ among these inorganic oxides, an organic electroluminescent element having an extremely high efficiency and a prolonged life can be provided. These hole-transporting materials may be used also as electron-blocking material.

As the electron-transporting layer among the aforementioned functional layers there may be used one made of an oxadiazole derivative such as 1,3-bis(4-tert-butylphenyl-1,3,4-oxadiazolyl)ₚ henylene (OXD-7), polymer material made of anthraquinodimethane derivative, diphenylquinone derivative or silol derivative, bis(2-m ethyl-8-quinolinolate)-(paraphenyl phenolate)aluminum (BAlq) or bathocuproin (BCP). The materials which can constitute an electron-transporting layer can be used also as hole-blocking material.

After the formation of the light-emitting layer 112, the cathode 113 is then formed. The cathode 113 is obtained by forming a metal such as Al into a layer using vacuum metallizing method or the like. As the cathode 113 of the electroluminescent element 110 there is used a metal or alloy having a low work function, e.g., metal such as Ag, Al, In, Mg and Ti, Mg alloy such as Mg—Ag alloy and Mg—In alloy, Al alloy such as Al—Li alloy, Al—Sr alloy and Al—Ba alloy. Alternatively, a metal laminate structure comprising a first electrode disposed in contact with the organic material layer made of a metal such as Ba, Ca, Mg, Li and Cs or fluoride or oxide thereof such as LiF and CaO and a second electrode made of a metallic material such as Ag, Al, Mg and In formed thereon may be used.

As mentioned above, the method for the production of the light-emitting device according to Embodiment 1 comprises the following steps.

i) A step of forming a light-detecting element 120 having an island-shaped semiconductor region (semiconductor island-shaped region A_{R}) on the glass substrate 100; and

ii) A step of forming an electroluminescent element 110 as a light-emitting element on the top of a flat portion of the island-shaped region A_{R} superimposed on the semiconductor island-shaped region A_{R} with an insulating film 122 interposed therebetween.

The step ii) comprises the following steps.
a) A step of forming a driving electrode (anode 111) of the electroluminescent element 110 covering the entire part of the semiconductor island-shaped region A_{R};
b) A step of covering a part of the driving electrode (anode 111) by an insulating film (pixel defining portion 114) and forming an opening at least inside the flat portion in the semiconductor island-shaped region A_{R} to define a light-emitting region (light-projecting region A_{LE});
c) A step of spreading a luminescent material over a portion including at least the opening by a so-called wet film-forming method to form a light-emitting layer 112; and
d) A step of forming other electrode (cathode 113) made of a metal as a main material on the spread of the luminescent material such that the light-emitting layer 112 is interposed between the other electrode (cathode 113) and the driving electrode (anode 111) to form an electroluminescent element 110.

In this arrangement, even when the light-emitting element and the light-detecting element are formed superimposed on each other, the light-emitting layer can be formed to a uniform thickness, making it possible to produce a light-emitting device having a uniform emission distribution and a prolonged life.

The light head according to Embodiment 1 as shown in FIG. 1 employs an arrangement such that light is outputted from the electroluminescent element 110 at the driving transistor 130 side thereof. Such a structure of the electroluminescent element 110 is called bottom emission. In order that such a bottom emission structure might allow the withdrawal of light on the glass substrate 100 side thereof, the light-detecting element 120 is preferably formed by a material having a high transparency as previously mentioned. The light-detecting element 120 is formed by, e.g., a polycrystalline silicon (polysilicon). The light-detecting element 120 made of a polycrystalline silicon is disadvantageous in that it is less capable of generating photocurrent than those made of amorphous silicon, but this problem can be solved by providing a capacitor (not shown) in the vicinity of the electroluminescent element 110 such that the charge according to the electric current outputted from the light-detecting element 120 is stored in the capacitor for a predetermined period of time or by providing a process circuit that stores a predetermined amount of charge, releases the charge and then converts it to a voltage. The bottom emission structure is advantageous in that it can be easily produced because the electrode (anode) on the light withdrawing side can be easily formed by a transparent material.

The light head. according to Embodiment 1 comprises a plurality of electroluminescent elements 110 aligned in the main scanning direction (direction of element line) as shown in FIG. 2. One light-detecting element 120 is disposed for each light-emitting region (light-projecting region A_{LE}). In this arrangement, the quantity of light emitted by the various electroluminescent elements 110 can be independently measured by the light-detecting element 120. The light-detecting element 120 and the electroluminescent element 110 are disposed with thin films (first insulating film 122, second insulating film 123 and protective film 124) interposed therebetween. Light leaks in the horizontal direction extremely little. Thus, the effect of optical crosstalk can be almost neglected. Thus, the quantity of light emitted by the plurality of electroluminescent elements 110 can be simultaneously measured, making it possible to drastically reduce the measuring time.

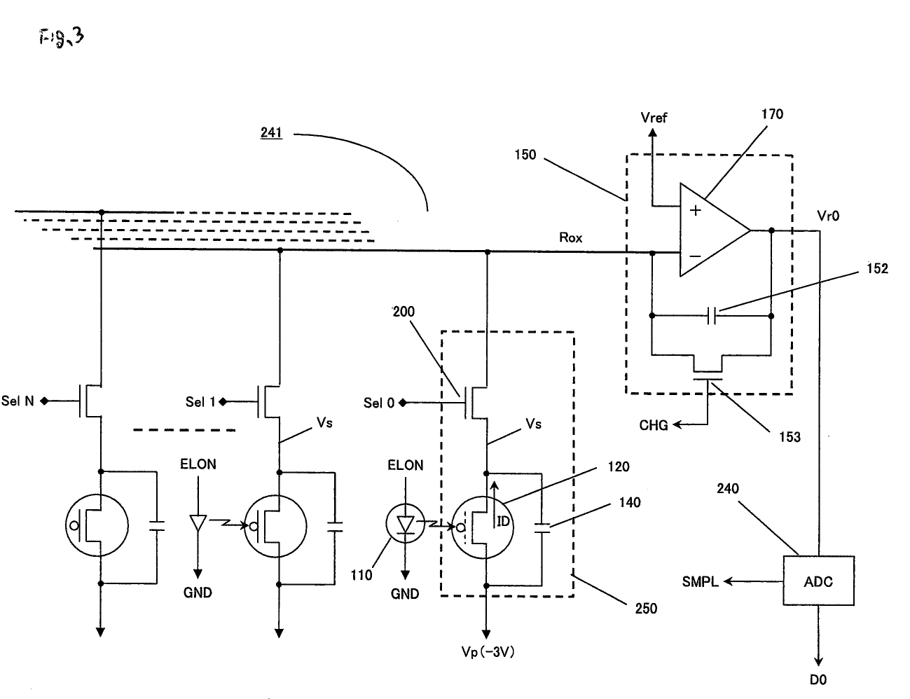

FIG. 2 depicts the mutual relationship of the light-detecting element 120, a drain electrode 125D as an output electrode of light-detecting element, a source electrode 125S as a grounding electrode of light-detecting element, an island-shaped region A_{R} as an element region of light-detecting element 120, ITO (indium tin oxide) which is an anode 111 of light-emitting layer 112, a through-hole HD and a drain electrode 134D. The light-detecting element 120 is connected to the drain electrode 125D as an output electrode of light-detecting element and the source electrode 125S as a grounding electrode of light-detecting element. The drain electrode 125D as an output electrode of light-detecting element is an electrode for transmitting an electric signal outputted from the light-detecting element 120 to the exterior of the light-detecting element 120 (described in detail later in connection with FIG. 3). On the basis of the electric signal is determined a feedback signal to be generated by a shading correction portion (not shown). A process required for the correction of quantity of light is effected on the basis of the feedback signal.

In Embodiment 1, the quantity of light emitted by the various electroluminescent elements 110 are corrected on the basis of the feedback signal. The electric current for driving the various electroluminescent elements 110 is controlled by a driver circuit which is not shown. While Embodiment 1 has been described with reference to the case where the quantity of light emitted by the electroluminescent element 110 is controlled on the basis of the output of the light-detecting element 120, an arrangement may be made such that a so-called PWM control, i.e., control over the driving time of the various electroluminescent elements 110 on the feedback signal is effected. The employment of PWM control is advantageous in that it can be realized by a full-digital circuit configuration.

The source electrode 125S as a grounding electrode of light-detecting element is an electrode for grounding the light-detecting element 120. ITO (indium tin oxide) which is an anode 111 of the electroluminescent element 110 as a light-emitting element is connected to the drain electrode 134D of a driving transistor 130. The electroluminescent element 110 is controlled by the driving transistor 130 via the drain electrode 134D.

As shown in FIGS. 1 and 2, the light head according to Embodiment 1 comprises island-shaped light-detecting elements 120 each composed of a polycrystalline silicon (polysilicon) aligned in a line. The various electroluminescent elements 110 each have a light-detecting element 120 having a semiconductor island region A_{R} provided under the light-emitting layer 112 having a light-projecting region A_{LE} limited by a silicon nitride film as a pixel limiting portion 114 wherein the semiconductor island region A_{R} is larger than the light-projecting region A_{LE}. By thus forming the semiconductor island region A_{R} (island-shaped polycrystalline portion) of the light-detecting element 120 larger than the light-projecting region A_{LE}, a structure such as source electrode 125S and drain electrode 125D is eliminated from the site at which the light-projecting region A_{LE}. Accordingly, at least the light-projecting region A_{LE} is formed on the flat portion of the light-detecting element 120. In this arrangement, even in the case where the light-emitting layer 112 is formed by the aforementioned wet method, the local thickness change of the light-emitting layer 112 can be suppressed, making it possible to prevent maldistributed flow of electric current through the light-emitting layer 112. Accordingly, a light head having a uniform emission distribution and a prolonged life can be produced.

Further, the island-shaped semiconductor island region A_{R} of the light-detecting element 120 to be incorporated in the light head employing the light-emitting device according to Embodiment 1 is larger than the light-emitting region, i.e., light-projecting region A_{LE}, making it possible to convert the light outputted from the light-emitting layer 120 into an electric signal to be used in the correction of the quantity of light or the emission time.

In the light head described in Embodiment 1, the electrode (anode 111) on the lower side of the electroluminescent element 110 which is a light-emitting element, the semiconductor region (semiconductor island region A_{R}) constituting the light-detecting element 120 and the light-projecting region A_{LE} are formed in this order of size decreasing, preferably by 1 μm or more. In an ordinary semiconductor process, the various layers can be difficulty formed or patterned completely according to drawing. In the case where patterning is made according to a large area without using any special device, an error of 1 μm or less occurs in the precision of positioning of photomask during photolithography, expansion and contraction of photomask, in-plane distribution of etching rate during etching or the like. Taking into account these factors, an error of about 1 μm normally occurs.

Accordingly, the provision of a margin having a size of 1 μm or more makes it possible to form a light-emitting device having a high reliability more efficiently even when any uneven distribution of thickness, position deviation, size deviation or the like occurs due to element production process. In the case where the size of the light-emitting device is increased, deviation due to element production process occurs more. Therefore, taking into account the related art ordinary process for the production of thin film transistor on glass substrate and other factors, the provision of a margin having a size of about 1 μm or more, the desired light-emitting device can be easily formed.

FIG. 3 is a circuit diagram of a light quantity detecting circuit 241 incorporated in the light head according to Embodiment 1.

The light quantity detecting circuit 241 to be used in the light head according to Embodiment 1 will be described hereinafter in connection with FIG. 3. The light quantity detecting circuit 241 comprises a driving IC having a charge amplifier 150 composed of an operational amplifier 170 and a detecting circuit Cx250 formed integrated on the glass substrate 100 (not shown in FIG. 3) so as to be connected to the input terminal of the driving IC as shown in FIG. 3. The detecting circuit Cx250 comprises a switching transistor 200, a light-detecting element 120 and a capacitor CS140 connected parallel to the light-detecting element 120 the charge stored in which is released as output current (photocurrent) from the light-detecting element 120. Though not shown in the sectional view of FIG. 1, the capacitor CS140 is formed by forming first and second insulating films 122, 123 interposed between electrically-conductive films formed at the step of connecting the capacitor CS140 to the source electrode 121S and drain electrode 121D of the light-detecting element 120. Taking into account the configuration of the light head, the capacitor CS140 is preferably disposed on the extension of the output electrode 125D of the light-detecting element shown in FIG. 2 (in the direction of subsidiary scanning).

Description will be made also in connection with FIG. 2.

The light-detecting element 120 detects the quantity of light by subjecting the light from the electroluminescent element 110 to photoelectric conversion in a channel region 121i formed by a polycrystalline silicon and then withdrawing the electric current flowing from the source region 121S to the drain region 121D as photocurrent.

However, when the electroluminescent element 110 is lighted during the measurement of the charge stored in the capacitor CS140, a predetermined voltage is applied to the anode 111 of the electroluminescent element 110 as previously mentioned. Therefore, the anode 111 acts as a gate electrode for the light-detecting element 120.

The potential at the gate electrode (anode 111) causes the application of an electric field to the polycrystalline silicon layer which is the channel region 121 of the light-detecting element 120, allowing the flow of drain current ID. Since the drain current ID is added to the current developed by the photoelectric conversion, the photoelectric current outputted from the drain electrode 125D to the detecting circuit Cx250 as sensor output is the actual photoelectric current plus the drain current ID. Thus, a problem arises that the precision of detection of quantity of light is deteriorated.

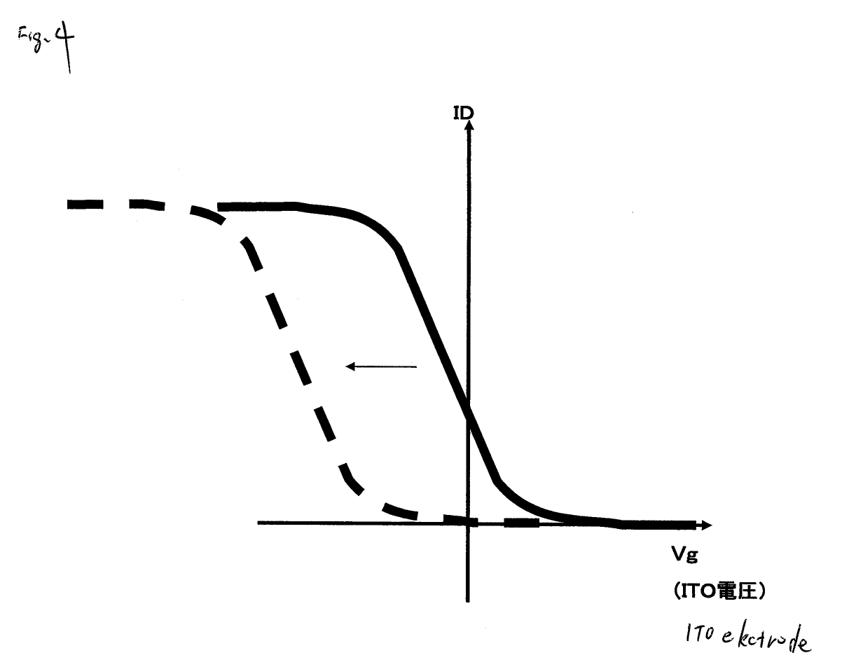

FIG. 4 is a diagram illustrating the relationship between the gate voltage Vg and the drain current ID of the light-detecting element 120 in Embodiment 1.

The results of measurement of the relationship between the gate voltage Vg and the drain current ID are shown by the solid line in FIG. 4. In order to assure a high precision of detection of quantity of light, the change of drain current ID with the gate voltage Vg is preferably small. Thereafter, as can be seen in FIG. 4, the light-emitting element is preferably used in the range within which the drain current ID of the thin film transistor is 0, i.e., the operation of the transistor is off (OFF range).

The relationship between the gate voltage Vg and the drain current ID involves a range within which current ID flows when Vg is greater than 0. In this range, the drain current ID varies with the gate voltage Vg. Therefore, the gate potential is shifted toward negative preferably as shown by the broken line in FIG. 4, making it possible to use the thin film transistor in OFF range and practically neglect dark current. In the invention, it is extremely important to detect the output of the light-detecting element 120 to a high precision. Thus, it is important to detect the light from the thin film transistor constituting the light-detecting element 120 in OFF range.

Description will be further made hereinafter in connection with FIG. 2.

The light-detecting element 120 is arranged such that the amount of the drain current ID and the photoelectric current are determined by the electric field applied to the polycrystalline silicon layer which is the channel region 121i of the thin film transistor constituting the light-detecting element 120. In this arrangement, when the channel region 121i of the thin film transistor is not partly covered by the anode 111, it is difficult to control the electric field applied to the area which is not covered by the anode 111. Thus, indefinite electric field generated by surface potential or external electric field can be applied to that area. In other words, the precision of detection of quantity of light can be deteriorated by external disturbance. Accordingly, when the light-detecting element 120 is arranged such that the polycrystalline silicon layer which is the channel region 121i of the thin film transistor is entirely covered by ITO electrode which is the anode 111 of the electroluminescent element 110, the channel can be more effectively controlled by the gate electric field.

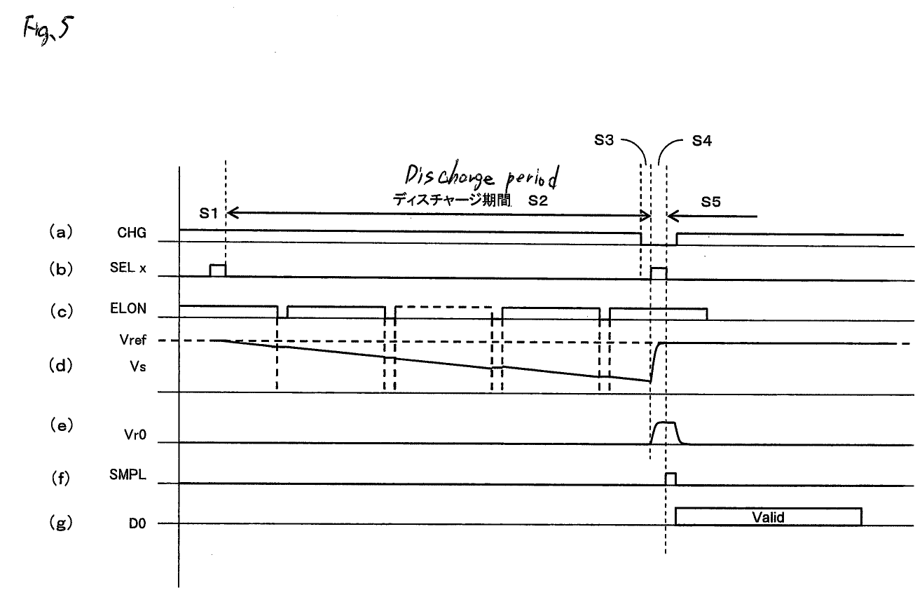

FIG. 5 is a timing chart illustrating the timing of detection of quantity of light in Embodiment 1.

Description will be further made in connection with FIG. 5 in combination with FIG. 3.

FIG. 5A depicts ON/OFF state of a switching transistor 153. The switching transistor 153 is capable of resetting the stored charge of a capacitance element 152. The charge period (more accurately discharge period as described later) of the capacitor CS140 is defined by ON/OFF of the switching transistor 153.

FIG. 5B depicts the operating timing of a switching transistor 200. ON/OFF of the switching transistor 200 is controlled on the basis of signal SELx When signal SELx is on a high level, the switching transistor 200 is ON.

FIG. 5C depicts the lighting timing of the electroluminescent element 110. In FIG. 5C, when signal ELON is on a high level, the electroluminescent element 110 emits light.

FIG. 5D depicts the change of potential at the both ends of the capacitor CS140 (e.g., between source electrode 125S and drain electrode 125D).

FIG. 5E depicts the output voltage of the operational amplifier 170.

FIG. 5F depicts the timing of sample-holding the output Vᵣ₀ of the operational amplifier 170.

FIG. 5G depicts the timing at which the analog signal thus sample-held is subjected to AD conversion in an AD converter 240 (from analog to digital) and the date thus digitized is then outputted.

Referring to the output of the light-detecting element 120, the quantity of light can be detected to a high precision by switching the switching transistor 200 so that the electric current charged in the capacitor CS140 for the period of time corresponding to the lighting time totaled by the predetermined number of times of lighting of the electroluminescent element 110 is withdrawn as shown in FIGS. 5A to 5G.

The operating timing in the operation of detection of quantity of light will be further described hereinafter.

Firstly, the switching transistor 200 is turned ON on the basis of signal DELx. The charge amplifier 150 causes the initial voltage V_{ref} to be charged in the capacitor CS140 (S1: reset step).

Subsequently, when the switching transistor 200 is turned OFF on the basis of signal SELx and signal ELON is controlled so as to light the electroluminescent element 110, the channel region 121i of the light-detecting element 120 which has received the light thus emitted (see FIG. 2) becomes electrically conductive in proportion to the quantity of light. During this period, the photocurrent flowing through the light-detecting element 120 causes the charge stored in the capacitor CS140 at reset step S1 to be reduced. In other words, the capacitor CS140 is discharged according to the quantity of light emitted by the electroluminescent element 110 (S2: lighting step).

Subsequently, the switching transistor 153 constituting the charge amplifier 150 is turned OFF on the basis of signal CHG to make the charge amplifier 150 capable of measuring the charge stored in the capacitor CS140 (S3: measurement starting step).

Subsequently, when the switching transistor 200 is turned ON on the basis of signal SELx, the charge which is stored in the capacitor CS140 at this time is then transferred to the capacitance element 152 constituting the charge amplifier 150. As a result, the output voltage Vᵣ₀ of the operational amplifier 170 constituting the charge amplifier 150 rises. Also during this period, the photocurrent flows through the light-detecting element 120 to raise Vᵣ₀, but the effect of the photocurrent can be almost neglected because it is a short-period microcurrent (S4: charge transfer step).

Finally, the switching transistor 200 is turned OFF on the basis of signal SELx to define Vᵣ₀. The output voltage Vᵣ₀ of the operational amplifier 170 thus defined is then taken into the AD converter 240 to terminate the operation of detecting the quality of light. Thus, the output D0 of the AD converter 240 (not shown) is defined (S5: read step).

The output D0 of the light quantity detecting circuit 241 thus obtained (digitized as already described) is then processed by a known assembled computer composed of, e.g., operational portion such as microcomputer, nonvolatile memory such as ROM having processing program housed therein, rewritable memory such as RAM for providing work region, etc. to be used in operation, bus for connecting these portions to each other, etc. to determine the quantity of light emitted and the emission time, which are driving conditions of the electroluminescent element 110.

In the case where the quantity of light emitted among these driving conditions of the electroluminescent element 110 is corrected, the light quantity correcting portion calculates a new driving voltage (or driving current) for each of the electroluminescent elements 110 constituting the light head. The driving parameter based on the results of calculation is then set in a driving condition setting portion which is not shown. In this manner, the driving conditions of the electroluminescent element 110 in the case where the driving transistor 130 (see FIG. 1) is turned ON are controlled.

In this arrangement, the voltage or current applied to the anode 111 and the cathode 113 of the electroluminescent element 110, which is a light-emitting element, is controlled so that a voltage is applied to the light-emitting layer 112 formed interposed therebetween, making it possible to compensate the change of quantity of light with the dispersion of the quantity of light emitted by the electroluminescent element 110 or with time and maintain uniform exposure.

While Embodiment 1 has been described with reference to the case where the electroluminescent element 110 and the light-detecting element 120 are formed superimposed on each other, they may not be disposed superimposed on each other. This structure corresponds to the case where the layer having the light-detecting element 120 formed therein and the layer having the light-emitting element (electroluminescent element 110) formed therein differ from each other, the light-emitting element 120 and the electroluminescent element 110 are disposed sufficiently apart from each other as viewed on plan view (top view) and the lower layer of the light-emitting element 120 is flat.

Further, as described later, in the case where one semiconductor region is subjected to doping or the like so that it is divided into an insulating region and an active region in which a plurality of light-emitting elements 120 are formed, the semiconductor region constituting each of the light-detecting element 120 is not island-shaped. Therefore, the light-detecting element 120 and the electroluminescent element 110 can be arranged superimposed partly on each other as viewed from the top.

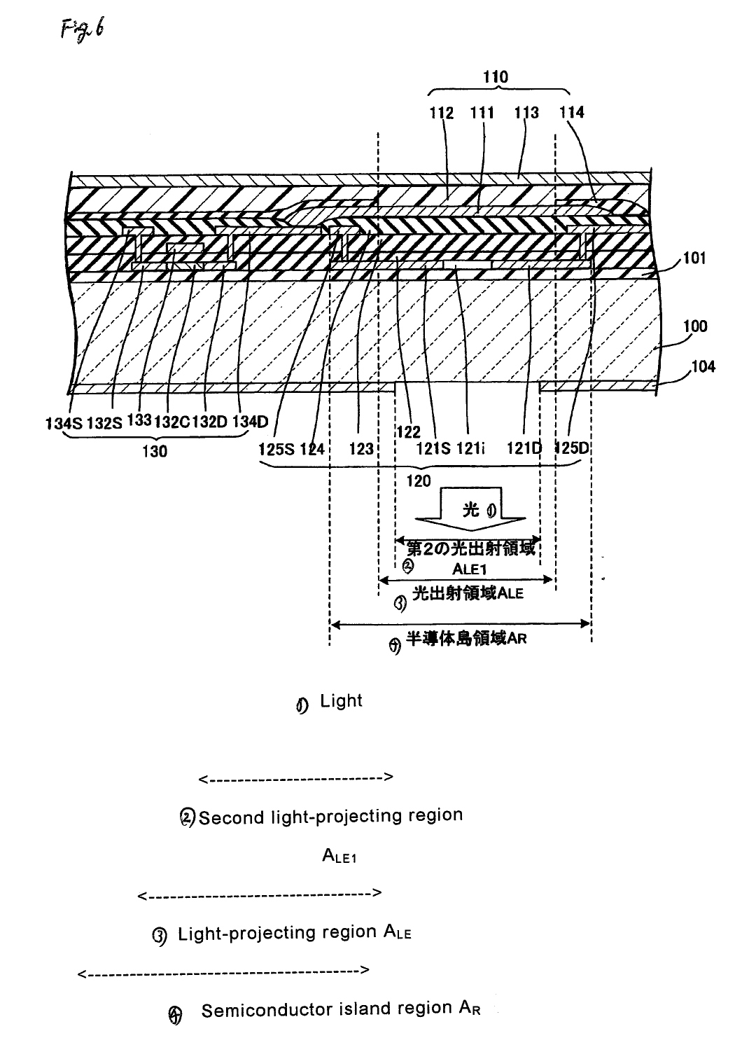

FIG. 6 is a sectional view illustrating a modification of the peripheral configuration of the electroluminescent element 110 in Embodiment 1.

As shown in FIG. 6, a light screening film 104 made of a thin chromium film or the like is formed on the back side (light withdrawing side) of a glass substrate. A second light-projecting region A_{LE1} is defined by an opening in the light screening film 104. In other words, the light-projecting region A_{LE1} is defined by an opening formed in the light screening film 104 provided closer to the light emission side than the light-projecting region A_{LE} of the electroluminescent element 110, which is a light-emitting element.

By forming the second light-projecting region A_{LE1} smaller than the opening in the image defining portion 114 already described, the uneven thickness portion of the light-emitting layer 112 produced due to the edge portion (constituting the level difference) of the image defining portion 114 can be removed from the light-projecting region A_{LE}. In particular, it is known that when a wet film-forming method is used to form the light-emitting layer 112, the thickness of the light-emitting layer 112 varies at the edge portion of the image defining portion 114. By thus forming the light screening film 104 separately, the distribution of quantity of light in the light-projecting region A_{LE1} (in-plane distribution of quantity of light) can be further uniformalized. The other configurations are the same as in Embodiment 1 above.

The light screening portion 104 can be referred to as an image defining portion that optically defines the light-emitting region (i.e., opening). As already described, the image defining portion 114 electrically defines the light-emitting region (i.e., opening as can be seen in FIG. 2) of the light-emitting element (electroluminescent element 110). Therefore, the configuration shown in FIG. 6 is no more than one illustrating the configuration of a light-emitting element “having a first image defining portion that electrically defines the light-emitting region of the light-emitting element and a second image defining portion that optically defines the light-emitting region of the light-emitting element”. Further, in other words, this configuration is a light-emitting element “comprising a light screening portion 104 provided inside an electrical image defining portion 114 as an optical image defining portion”.

In the case where the aforementioned configuration is employed, one of the focuses of the optical system through which the light emitted by the light head is introduced into the photoreceptor is preferably the surface of the second light-projecting region A_{LE1} (surface of the glass substrate 100 on the light emitting side thereof). Of course, the other focus is set on the surface of the photoreceptor. In this arrangement, a sharp latent image can be formed on the photoreceptor.

### Embodiment 2

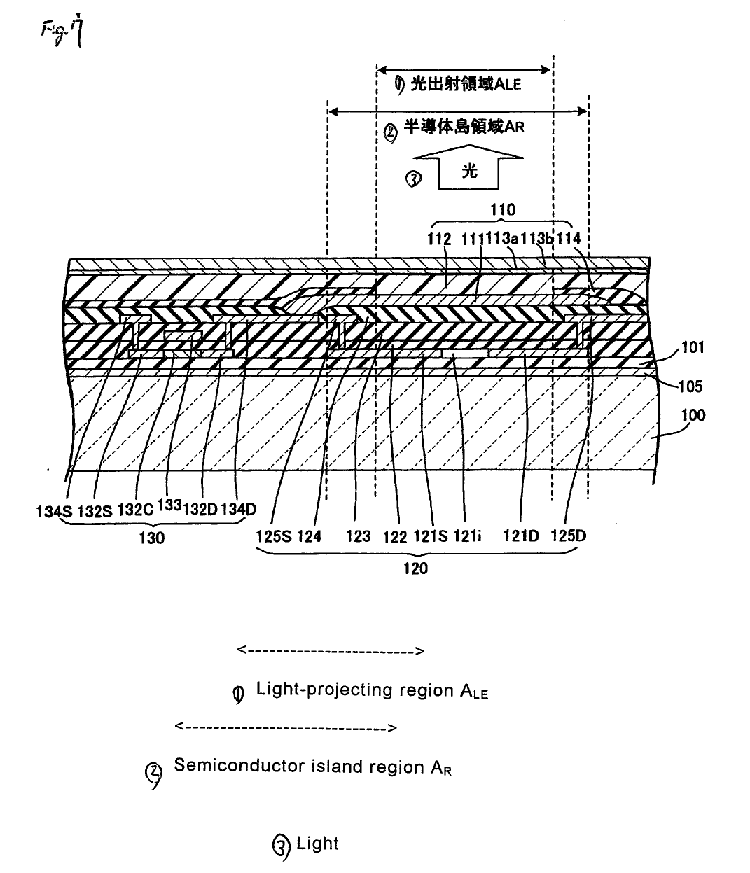

FIG. 7 is a sectional view of the light head according to Embodiment 2 in the form of top emission structure. The term “top emission structure” as used herein is meant to indicate a structure arranged such that the light outputted from the light-emitting layer 112 propagates toward cathodes 113a and 113b provided on the top of the light-emitting element 112 (surface of the glass substrate 100 having the thin film transistor and electroluminescent element 110 formed thereon) as opposed to the bottom emission structure.

In the configuration of FIG. 7, a reflective layer 105 made of a metal is provided on the glass substrate 100 so that the light is emitted in the direction toward the cathode. In FIG. 7, the reflective layer 105 is electrically connected to an electrode which is not shown or the like. By properly controlling the potential at the electrode, the light-detecting element 120 can be operated as a so-called bottom gate type transistor. In this manner, a light-emitting element 120 that cannot be affected by the potential applied to the anode 111 of the electroluminescent element 110 formed on the top of the light-detecting element 120 can be realized. In this case, it goes without saying that the distance between the reflective layer 105 and the light-detecting element 120 and the voltage applied to the reflective layer 105 are important.

In the top emission structure, an opaque substrate may be used instead of the glass substrate 100. In this case, the aforementioned reflective layer 105 is preferably provided on the surface of the substrate. As the material of the reflective layer 105 there is preferably used a metal for the same reason as mentioned above.

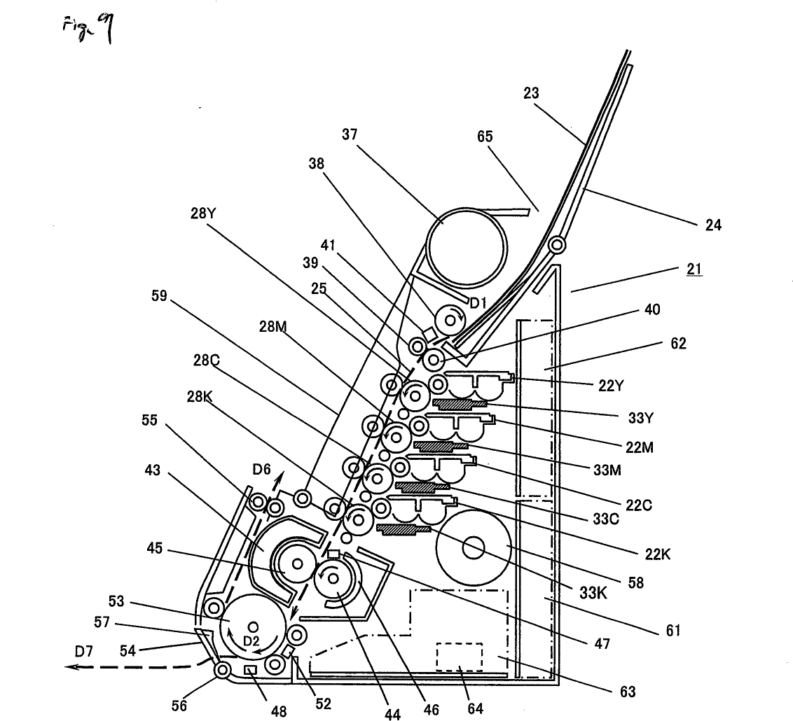

In the case where this structure is employed, the photoreceptor which is not shown (see 28Y to 28K of FIG. 9 as described later) is exposed to light emitted in the direction opposite the light-detecting element 120 among the light components generated in the light-emitting layer 112 of the electroluminescent element 110 as shown in the drawing. On the other hand, the light generated in the light-emitting layer 112 is emitted also in the direction opposite exposure side, i.e., toward the light-emitting element 120. This light component is then received by the light-detecting element 120.

In the case where the top emission structure is employed, about half the light components to be used in exposure pass through the light-detecting element 120, and are then reflected by the reflective layer 105. As the light-detecting element 120 there may be arbitrarily selected any of a polysilicon silicon having a high transparency but somewhat deteriorated capability of generating photocurrent and an amorphous silicon having somewhat deteriorated transparency but a high capability of generating photocurrent. In Embodiment 2, an amorphous silicon having a high capability of generating photocurrent is used to form the light-emitting element 120. In the top emission structure that allows the withdrawal of light on the side thereof opposite the glass substrate 100, the light emitted by the electroluminescent element 110 is directly incident on the light-detecting element 120. The light emitted by the electroluminescent element 110 is also reflected by the reflective layer 105 and is then incident on the light-detecting element 120. In this arrangement, the light reflected by the reflective layer 105, too, makes contribution to the detection of quantity of light, enhancing the precision of detection.

In order to realize the top emission structure, it is necessary that the transparent electrode 113b be formed on the organic luminescent material as a cathode. In order that the organic luminescent material constituting the light-emitting layer 112 might not be damaged during the formation of the transparent electrode, a laminate of an extremely thin metal layer 113a made of Al, Ag or the like (thin film cathode) and a transparent electrode 113b such as ITO is used as a cathode as shown in FIG. 7. The metal layer 113a is extremely thin and thus can be sufficiently provided with transparency. Further, due to its work function, the metal layer 113a allows efficient injection of electron into the light-emitting layer. The provision of the transparent electrode 113b having a sufficient thickness on the surface of the metal layer makes it possible to realize a low resistance cathode provided with transparency. Alternatively, a metal oxide or polymer material can be formed as a buffer layer to relax the damage on the transparent electrode 113b during its formation. Further, a top emission structure similar to the related art structure simply except that the upper and lower elements are exchanged by each other, i.e., top emission structure comprising a cathode as a lower electrode and an anode as an upper electrode can be employed. The top emission structure requires more production steps than the bottom emission structure and adds to production cost but can constitute a light head having a high emission efficiency.

The configuration and action of the electroluminescent element 110 and the light-detecting element 120 constituting the light head will be described in detail hereinafter. While Embodiment 1 has been described with reference to the case where the light-emitting elements (electroluminescent elements 110) are aligned in a line in the light head, these electroluminescent elements 110 may be aligned in a plurality of lines to substantially enhance the quantity of light emitted.

Referring to the structure of the electroluminescent element 110 and the light-detecting element 120 described above, they may be two-dimensionally aligned to form a light-emitting device that can be applied to the display device such as display which is one of the applications of the light-emitting device.

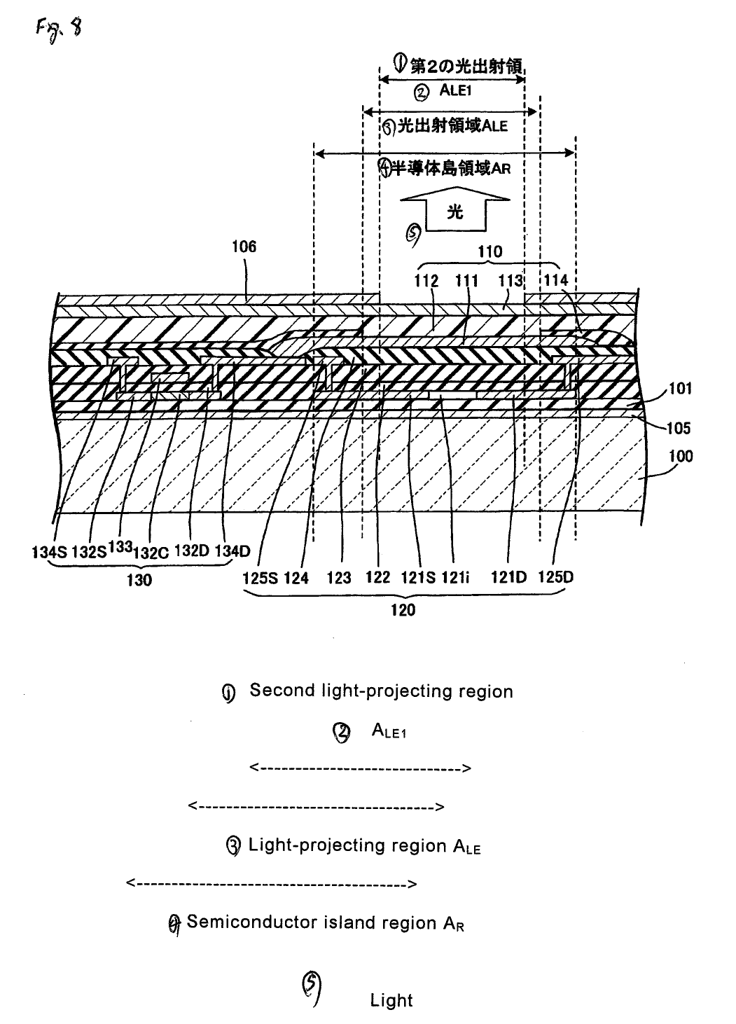

FIG. 8 is a sectional view illustrating a modification of the peripheral configuration of the electroluminescent element according to Embodiment 2.

As shown in FIG. 8, a top emission structure may be employed and a light screening film 106 made of a thin chromium film may be formed on the structure on the side thereof allowing the withdrawal of light wherein a second light-projecting region A_{LE1} is defined by an opening in the light screening film 106. By forming the second light-projecting region A_{LE1} smaller than the opening in the silicon nitride film as the image defining portion 114 described in Embodiment 1 above, the level difference on the light-emitting layer 112 due to the silicon nitride can be removed from the light-projecting region A_{LE1}, making it possible to further uniformalize the thickness of the light-emitting layer 112. The other configurations are the same as in Embodiment 1 above.

As in the description of Embodiment 1 in connection with FIG. 6, it is particularly significant also in the structure shown in FIG. 8 to provide the light screening film 106 in the case where the light-emitting layer of the light-emitting device represented by light head is produced by a wet film forming method.

### Embodiment 3

FIG. 9 is a configurational diagram of an image forming device 21 comprising a light-emitting device according to Embodiment 3 as a light head.

In FIG. 9, the image forming device 21 comprises four color development stations, i.e., yellow development station 22Y, magenta development station 22M, cyan development station 22C and black development station 22K aligned vertically stepwise thereinside. Above the device is provided a paper feed tray 24 for receiving recording paper 23. Recording paper conveying paths 25 through which recording paper 23 supplied from the paper feed tray 24 is conveyed are disposed at the sites corresponding to the various development stations 22Y to 22K, respectively, along the vertical direction extending from top to bottom.

The development stations 22Y to 22K are adapted to form yellow, magenta, cyan and black toner images, respectively, as viewed from the top one of the recording paper conveying paths 25. The yellow development station 22Y comprises a photoreceptor 28Y, the magenta development station 22M comprises a photoreceptor 28M, the cyan development station 22C comprises a photoreceptor 28C, and the black development station 22K comprises a photoreceptor 28K. Further, the various development stations 22Y to 22K each comprise members that realize a development process in a continuous electrophotographic process, e.g., development sleeve which is not shown and charger.

Below the various development stations 22Y to 22K are provided exposure devices 33Y, 33M, 33C and 33K for exposing the surface of the photoreceptors 28Y to 28K to light to form a latent image thereon, respectively. The light head described in Embodiment 1 is incorporated in the exposure devices 33Y, 33M, 33C and 33K.

The development stations 22Y to 22K are filled with developers having different colors. However, these development stations have the same configuration regardless of developed color. Therefore, for the sake of simplification of description, the following description will be made without identifying specific color, e.g., development station 22, photoreceptor 28, exposure device 33, unless otherwise specifically required.

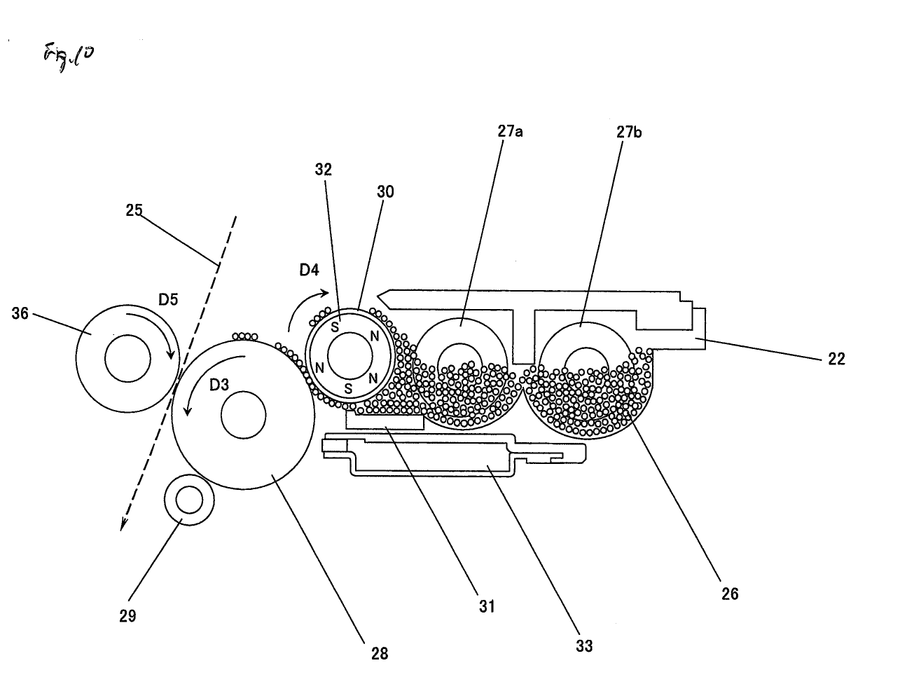

FIG. 10 is a configurational diagram illustrating the periphery of the development station 22 in the image forming device 21 according to Embodiment 3. In FIG. 10, the interior of the development station 22 is filled with a developer 26 which is a mixture of carrier and toner. The reference numerals 27a, 27b each are an agitation paddle for agitating the developer 26. The rotation of the agitation paddles 27a and 27b causes the toner in the developer 26 to be charged to a predetermined potential by friction with the carrier. At the same time, the developer 26 is circulated inside the development station 22, causing the toner and the carrier to be thoroughly agitated. The photoreceptor 28 is rotated in the direction D3 by a driving source which is not shown. The reference numeral 29 indicates a charger which is adapted to charge the surface of the photoreceptor 28 to a predetermined potential. The reference numeral 30 indicates a development sleeve and the reference numeral 31 indicates a thinning blade. The development sleeve 30 has a magnet roll 32 comprising a plurality of magnetic poles formed therein. The thinning blade 31 defines the thickness of the developer 26 to be supplied onto the surface of the development sleeve 30. At the same time, the development sleeve 30 is rotated in the direction D4 by a driving source which is not shown. The rotation of the development sleeve 30 and the action of the magnetic poles of the magnet roll 32 cause the developer 26 to be supplied onto the surface of the development sleeve 30 to develop a latent image which has been formed on the photoreceptor 28 by an exposure device described later. At the same time, the developer 26 which has not been transferred to the photoreceptor 28 is recovered by the interior of the development station 22.

The reference numeral 33 indicates the exposure device described already. In the image forming device 21 employing the exposure device 33 having the light head described in detail in Embodiment 1 or 2 incorporated therein, the exposure device 33 can form a latent image stably over an extended period of time as already described. Therefore, the image forming device has a prolonged life. Further, the exposure device 33 having the light head according to Embodiment 1 incorporated therein can provide an electrostatic latent image having a desired shape over an extended period of time. Therefore, the image forming device can always form a high quality image.

The exposure device 33 according to Embodiment 3 has electroluminescent elements 110 (see FIG. 1, etc.) aligned in a straight line at a resolution of 600 dpi (dot/inch). The electroluminescent elements 110 are selectively turned ON/OFF according image date with respect to the photoreceptor 28 which has been charged to a predetermined potential by the charger 29 to form an electrostatic latent image having a size of A4 at maximum. To the electrostatic latent image portion is then attached only the toner in the developer 26 which has been supplied onto the surface of the development sleeve 30 to develop the electrostatic latent image.

The electroluminescent element 110 used in Embodiment 3 is an organic electroluminescent element. As described in detail in Embodiment 1, a light-detecting element 120 (see FIG. 1, etc.) is provided. The quantity of light emitted by the electroluminescent element 110 is corrected on the basis of the quantity of light detected by the light-detecting element 120.

A transfer roller 36 is provided at the site opposed to the recording paper conveying path 25 with respect to the photoreceptor 28. The transfer roller 36 is rotated in the direction D5 by a driving source which is not shown. A predetermined transfer bias is applied to the transfer roller 36 so that the toner image formed on the photoreceptor 28 is transferred to recording paper which has been conveyed along the recording paper conveying path 25.

Description will be further made in connection again with FIG. 9.

As has been described, the image forming device 21 according to Embodiment 3 is a tandem type color image forming device having a plurality of development stations 22Y to 22K aligned vertically stepwise and is intended to have a size equal to that of color ink jet printers. The development stations 22Y to 22K each have a plurality of units provided therein. Therefore, in order to reduce the size of the image forming device 21, it is necessary that the size of the development stations 22Y to 22K themselves be reduced. At the same time, it is necessary that the size of members taking part in imaging process disposed in the periphery of the development stations 22Y to 22K be reduced to minimize the disposition pitch of the development stations 22Y to 22K.

Taking into account the users' convenience during the installment of the image forming device 21 on the desk top in offices, etc., particularly access to recording paper 23 during paper feed or discharge, the height of the image forming device 21 from the bottom to the paper feed port 65 is preferably 250 mm or less. To this end, it is necessary that the entire height of the development stations 22Y to 22k in the entire configuration of the image forming device 21 be suppressed to about 100 mm.

However, the existing member, e.g., LED head has a thickness of about 15 mm. When LED head is disposed in the gap between the development stations 22Y to 22K, it is difficult to accomplish the aforementioned purpose. The results of study by the inventors show that when the thickness of the exposure device 33 is 7 mm or less, the entire height of the development stations can be suppressed to 100 mm or less even if the exposure devices 33Y to 33K are disposed in the gap between the development stations 22Y to 22K, respectively.

The reference numeral 37 indicates a toner bottle having yellow, magenta, cyan and black toners received therein, respectively. A toner conveying piper which is not shown is provided between the toner bottle 37 and each of the various development stations 22Y to 22K so that the toner is supplied into the various development stations 22Y to 22K.

The reference numeral 38 is a paper feed roller which is rotated in the direction D1 by controlling an electromagnetic clutch which is not shown so that recording paper 23 packed in the paper feed tray 24 is delivered to the recording paper conveying path 25.

The recording paper conveying path 25 disposed between the paper feed roller 38 and the transfer site of the yellow development station 22Y, which is the uppermost development station, is provided with a pair of resist roller 39 and pinch roller 40 as nip conveying means at the inlet side. The pair of resist roller 39 and pinch roller 40 temporarily stops the recording paper 23 which has been conveyed from the paper feed roller 38 and then conveys the recording 23 toward the yellow development station 22Y at a predetermined time. The temporary stop causes the forward end of the recording paper 23 to be defined parallel to the axial direction of the pair of resist roller 39 and pinch roller 40, preventing the recording paper 23 from running obliquely.

The reference numeral 41 indicates a recording paper passage detecting sensor. The recording paper passage detecting sensor 41 is composed of a reflective sensor (photoreflector) which senses the presence or absence of reflected light to detect the forward and rear ends of the recording paper 23.

When the rotation of the resist roller 39 begins (power transfer is controlled by an electromagnetic clutch to make ON/OFF of rotation), the recording paper 23 is conveyed toward the yellow development station 22Y along the recording paper conveying path 25. The timing of writing of electrostatic latent image by the exposure devices 33Y to 33K disposed in the vicinity of the various development stations 22Y to 22K, respectively, are independently controlled with the timing of starting of rotation of the resist roller 39 as a starting point.

At the recording paper conveying path 25 disposed under the black development station 22K, which is the lowermost development station, is provided a fixing device 43 as an outlet side nip conveying means. The fixing device 43 is composed of a heating roller 44 and a pressure roller 45. The heating roller 44 is a multi-layered roller composed of a heating belt, a rubber roller and a core material (all not shown) in this order as viewed from the surface thereof. Among these members, the heating belt is a belt having a three-layer structure, i.e., release layer, silicon rubber layer, substrate layer (all not shown) in this order as viewed from the surface thereof. The release layer is made of a fluororesin having a thickness of from about 20 μm to 30 μm that renders the heating roller 44 releasable. The silicon rubber layer is composed of a silicon rubber having a thickness of about 170 μm that renders the pressure roller 45 properly elastic. The substrate layer is composed of a magnetic material which is an alloy such as iron-nickel-chromium.

The reference numeral 46 indicates a rear core having an exciting coil incorporated therein. Inside the rear core 46 is provided an exciting coil comprising a predetermined number of copper wires (not shown) combined in a bundle extending in the direction of rotary axis of the heating roller 44 and around in the peripheral direction of the heating roller 44 a the both ends of the heating roller 44. When an ac current of about 30 KHz from an exciting circuit (not shown) which is a semi co-oscillation inverter is applied to the exciting coil, a magnetic flux is generated in a magnetic path composed of the rear core 46 and the base layer of the heating roller 44. The magnetic flux thus generated causes the base layer of the heating belt of the heating roller 44 to form eddy current that causes the base layer to generate heat. The heat generated in the base layer is then transferred to the release layer through the silicon rubber layer to cause the surface of the heating roller 44 to generate heat.

The reference numeral 47 indicates a temperature sensor for detecting the temperature of the heating roller 44. The temperature sensor 47 is a ceramic semiconductor obtained by sintering a metal oxide as a main raw material at high temperature. The temperature 47 makes the use of the change of load resistance with temperature to measure the temperature of the object in contact therewith. The output of the temperature sensor 47 is inputted to a controller which is not shown. The controller controls the electric power to be inputted to the exciting coil in the rear core 46 on the basis of the output of the temperature sensor 47 such that the surface temperature of the heating roller 44 reaches about 170° C.

When the recording paper 23 having a toner image formed thereon passes through the nip portion formed by the heating roller 44 which has been temperature-controlled and the pressure roller 45, the toner image on the recording paper 23 is then heated and pressed by the heating roller 44 and the pressure roller 45, respectively, so that the toner image is fixed on the recording paper 23.

The reference numeral 48 indicates a recording paper rear end detecting sensor which monitors how the recording paper 23 is discharged. The reference numeral 52 is a toner image detecting sensor. The toner image detecting sensor 52 is a reflective sensor unit comprising electroluminescent elements (all emitting visible light) as a plurality of light-emitting elements having different emission spectrum and a single light-receiving element (light-detecting element). By making the use of the fact that absorption spectrum differs from the background of the recording paper 23 to the image area depending on the image color, the toner image detecting sensor 52 detects the image density. Since the toner image detecting sensor 52 can detect not only the image density but also the image forming site, the image forming device 21 according to Embodiment 1 has a toner image detecting sensor 52 provided at two sites in the width direction of the image forming device 21 such that the image forming timing is controlled on the basis of the site of detection of an image position deviation detection pattern formed on the recording paper 23.

The reference numeral 53 indicates a recording paper conveying drum. The recording paper conveying drum 53 is a metallic roller covered by a rubber having a thickness of about 200 μm. The recording paper 23 having a toner image fixed thereon is conveyed in the direction D2 along the recording paper conveying drum 53. During this period, the recording paper 23 is conveyed bent against the image formation area while being cooled by the recording paper conveying drum 53. In this manner, curling generated when a high density image is formed on the entire surface of the recording paper can be drastically eliminated. Thereafter, the recording paper 23 is conveyed in the direction D6 by a kick roller 55, and then discharged into the paper discharge tray 59.

The reference numeral 54 indicates a face down paper discharge portion. The face down paper discharge portion 54 is arranged rotatable on a supporting member 56. When the face down paper discharge portion 54 is kept open, the recording paper 23 is discharged in the direction D7. When the face down paper discharge portion 54 is kept closed, ribs 57 are formed on the back side thereof along the conveying patch such that the conveyance of the recording paper 23 is guided together with the recording paper conveying drum 53.

The reference numeral 58 indicates a driving source which is a stepping motor in Embodiment 1. The driving source 58 drives the periphery of the various development stations 22Y to 22K, including the paper feed roller 38, the resist roller 39, the pinch roller 40, the photoreceptors (28Y to 28K), and the transfer rollers (36Y to 36K), the fixing device 43, the recording paper conveying drum 53 and the kicking roller 55.

The reference numeral 61 is a controller which receives image data from a computer which is not shown, etc. via an external network and develops and produces printable image data.

The reference numeral 62 is an engine controlling portion. The engine controlling portion 62 controls the hardware and mechanism of the image forming device 21, forms a color image on the recording paper 23 on the basis of image data transferred from the controller 61 and performs control over the image forming device 21 at large.

The reference numeral 63 is a power supply portion. The power supply portion 63 supplies an electric power of a predetermined voltage into the exposure devices 33Y to 33K, the driving source 58, the controller 61 and the engine controlling portion 62 and supplies electric power into the heating roller 44 of the fixing device 43. A so-called high voltage electric power such as charge on the surface of the photoreceptor 28, development bias to be applied to the development sleeve (see reference numeral 30 in FIG. 7) and transfer bias to be applied to the transfer roller 36 is included in the electric power supplied from the power supply portion.

Further, the power supply 63 comprises a power supply monitoring portion 64 adapted to monitor at least the power voltage to be supplied into the engine controlling portion 62. The monitor signal is detected in the engine controlling portion 62 to detect the drop of the power voltage generated during OFF of power supply switch, power breakdown, etc.

While the foregoing description has been made with reference to the case where the invention is applied to color image forming devices, the invention may be applied to devices for forming a monochromatic image such as black image. In the case where the invention is applied to color image forming devices, the colors to be developed are not limited to the four colors, i.e., yellow, magenta, cyan and black.

The image forming device 21 of the invention has exposure devices 33Y to 33K having a uniform emission distribution and an excellent durability incorporated therein and thus exhibits an excellent image quality and durability.

### Embodiment 4

While Embodiment 1 has been described with reference to the case where as the light-detecting element there is used a thin film transistor, the light-detecting element to be used in the light-emitting device of the invention is not limited thereto and NPN transistor, PN photodiode or PN diode may be used. In the case where a photodiode structure is employed in particular, the light-detecting element has rectifying properties and thus can easily detect electric current. In particular, PIN photodiode has a high sensitivity to light and thus can easily realize a high sensitivity light-detecting element.

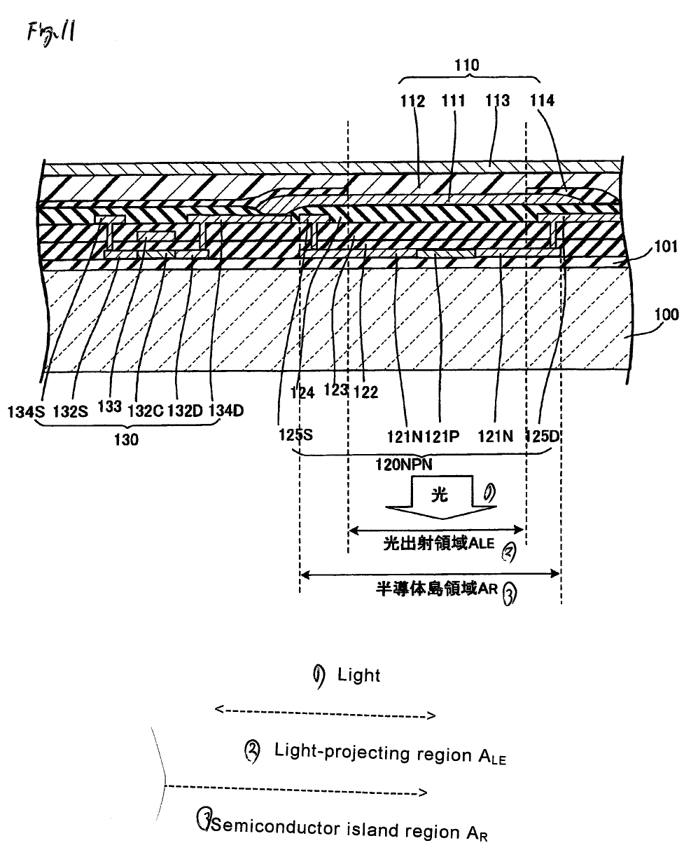

FIG. 11 is a sectional view illustrating a light-emitting device according to Embodiment 4.

The light-emitting device shown in FIG. 11 comprises an NPN transistor as a light-detecting element 120NPN.

As can be seen in FIG. 11, the NPN transistor constituting the light-detecting element 120NPN has an island-shaped semiconductor region composed of polycrystalline silicon N layer 121N, polycrystalline silicon P layer 121P and polycrystalline silicon N layer 121N which are each connected to the source electrode 125S and the drain electrode 125D via through-holes formed in the insulating films 122, 123.

The other configurations are the same as in Embodiment 1.

In this case, too, it is desired that a polysilicon silicon having a good transparency be used in the semiconductor region.

### Embodiment 5

The present embodiment will be described with reference to the case where as the light-detecting element there is used a photodiode.

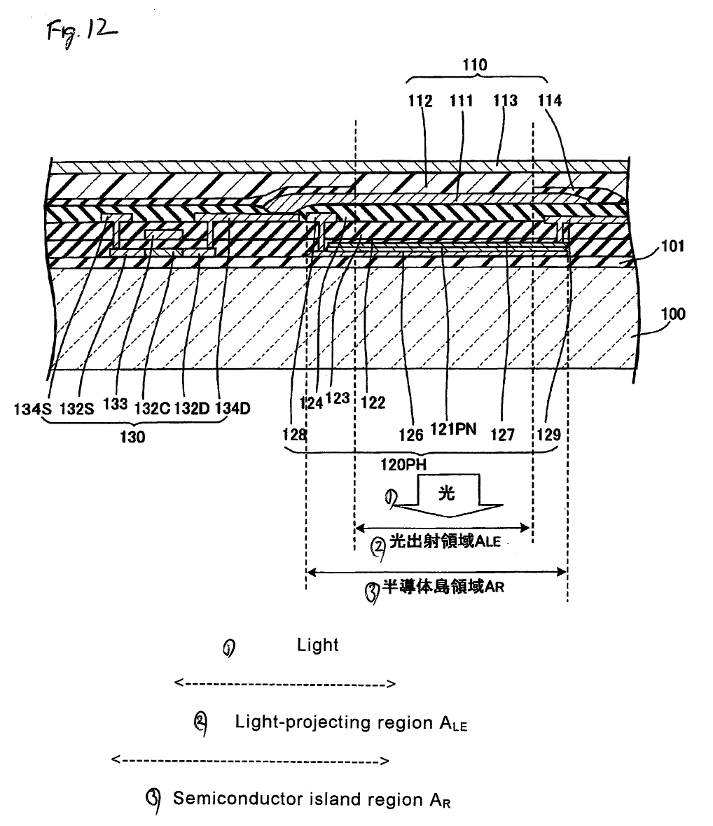

FIG. 12 is a sectional view illustrating a light-emitting device according to Embodiment 5.

The light-emitting device shown in FIG. 12 comprises a structure having a photodiode 120PH laminated on the surface of the glass substrate 100 as a light-detecting element.

As can be seen in FIG. 12, in the case where a structure having a photodiode 120PH laminated therein is employed, the photodiode 120PH to be used as a light-detecting element has an island-shaped semiconductor region (polycrystalline silicon layer 121PN produced by doping such that a junction of polycrystalline silicon N layer and polycrystalline silicon P layer is produced) provided interposed between light-transmitting first and second electrodes 126 and 127, which photodiodes 120PH are each connected to the source electrode 128 and the drain electrode 129 via through-holes formed in the first and second insulating films 122, 123. While the present embodiment has been described with reference to PN junction type photodiode, a PIN structure having an intrinsic region I layer formed interposed between P layer and N layer may be employed, making it possible to realize a light-detecting element having a higher sensitivity. It goes without saying that an NP type structure obtained by reversing the position of P layer and N layer may be employed. Originally, the photodiode 120PH doesn't have any gate electrode formed therein as in thin film transistors. However, in order to effect stable detection of light free from effect of external electric field, an electrode is preferably formed on the interface if a PN junction type structure is employed or on the intrinsic region I layer if a PIN structure is employed to control the potential in the light-detecting region.

The other portions are the same as in Embodiment 1.

In this case, too, a polycrystalline silicon having a good transparency is preferably used in the semiconductor region. It is also necessary that the anode 111 and the cathode 113 be made of light-transmitting ITO. In the case where the structure comprising the photodiode 120PH is applied to the top emission structure, the first electrode 126 constituting the photodiode 120PH can be used as a reflective electrode, eliminating the necessity of forming any separate reflective layer and hence simplifying the element production process to advantage.

### Embodiment 6

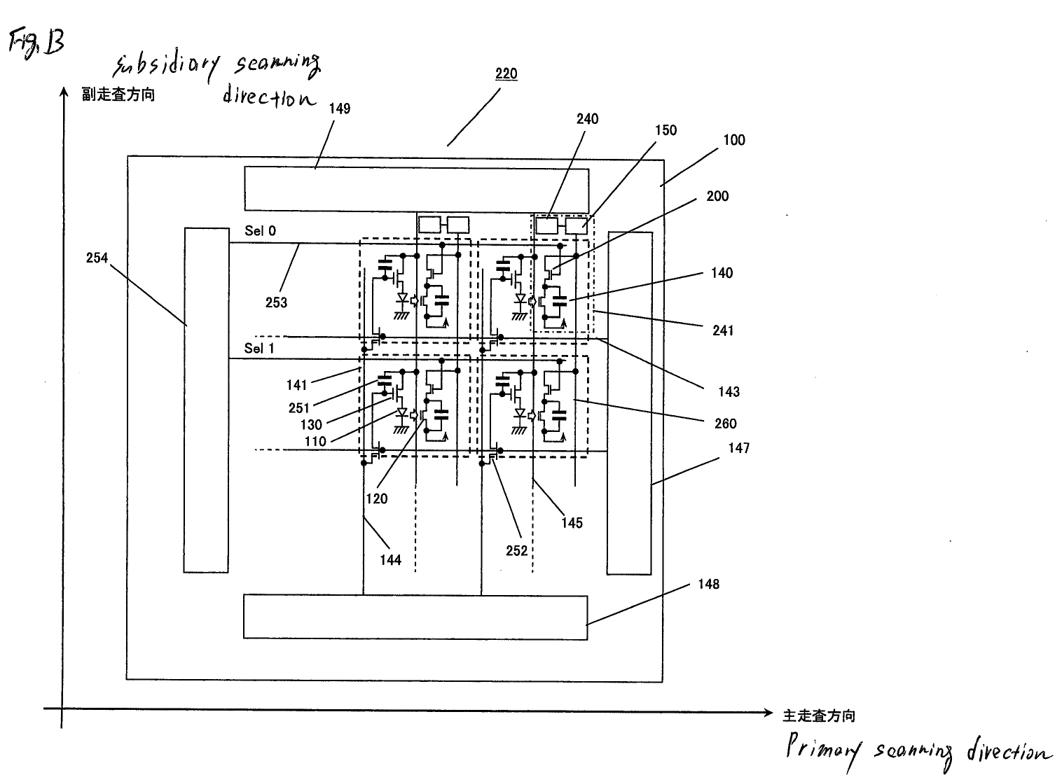

FIG. 13 is a configurational diagram of a display device employing the light-emitting device according to Embodiment 6.

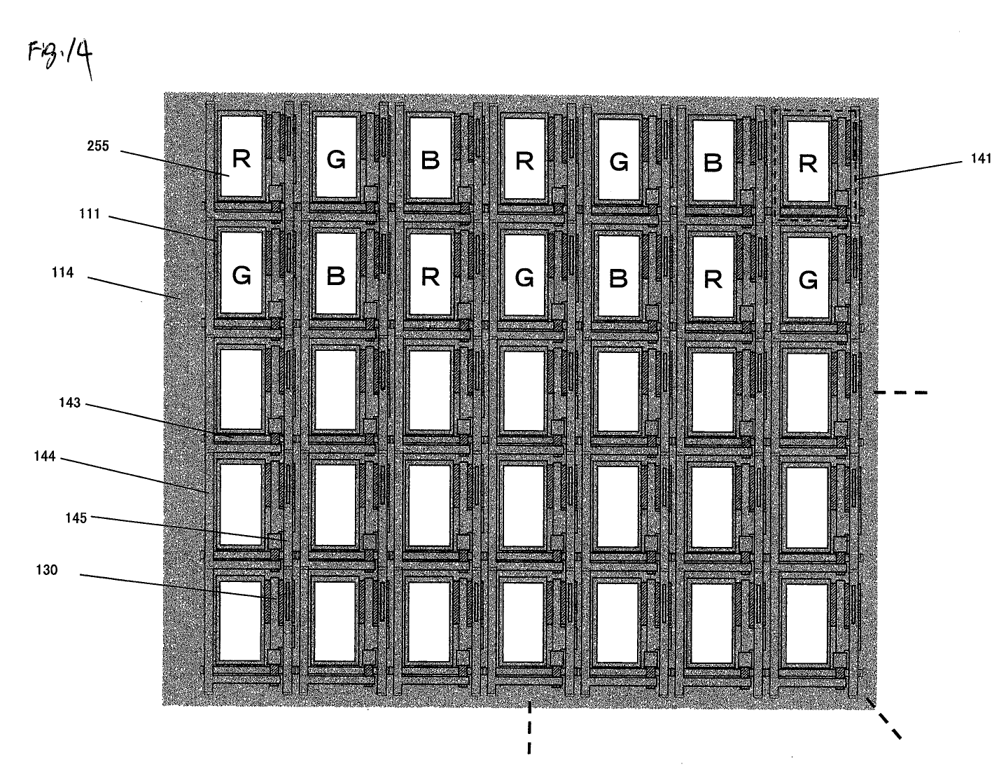

FIG. 14 is a diagram illustrating the configuration of pixels of the display device according to Embodiment 6.

The display device employing the light-emitting device of the invention will be described hereinafter in connection with FIGS. 13 and 14.

In the display device according to Embodiment 6, the light-emitting layers 112 of the electroluminescent element 110 (all not shown, see FIG. 1, etc.) are formed by an ink jet method. FIG. 13 depicts a circuit configuration of the active matrix type display device.

As shown in FIGS. 13 and 14, the display device according to Embodiment 6 is an active matrix type display device 220 comprising display pixels 141 each having electroluminescent elements 110 as light-emitting element and light-detecting elements 120 for receiving light emitted by the electroluminescent elements 110.

The display device 220 has a plurality of display pixels 141 aligned in the primary scanning direction and subsidiary scanning direction as shown in FIG. 13.

The display pixels 141 each have an electroluminescent element 110 and a light-detecting element 120 for receiving light emitted by the electroluminescent element 110. As described in detail in Embodiment 1, etc., the electroluminescent element 110 and the light-detecting element 120 are formed superimposed on each other on the glass substrate 100. The light-projecting region A_{LE} Of the electroluminescent element 110 is disposed inside the semiconductor island region A_{R} constituting the light-detecting element 120 (see FIG. 1).

The procedure for measuring the quality of light emitted by the electroluminescent element 110 has been described in detail in Embodiment 1 and thus will not be described hereinafter.

In FIG. 13, the reference numeral 143 indicates a scanning line, the reference numeral 144 indicates a signal line (data line), the reference numeral 145 indicates a common power supply line, the reference numeral 253 indicates a light-detection scanning line, the reference numeral 147 indicates a scanning line driver, the reference numeral 148 indicates a signal line driver, the reference numeral 149 indicates a common power supply line driver, and the reference numeral 254 indicates a light detection scanning line driver.

The gate electrode of a selective transistor 252 of each of the various display pixels 141 aligned in the primary scanning direction is connected to the scanning line 143 to give a scanning signal. The drain electrode of a selective transistor 252 of each of the various display pixels 141 aligned in the subsidiary scanning direction is connected to the signal line (data line) 144 to provide a signal based on the emission intensity. One of the electroluminescent element 110 is connected to the common power supply line 145 via a driving transistor 130 and the other is grounded.

Further, the light-detecting element 120 having a capacitor CS140 connected to the both ends thereof is connected to a predetermined power supply (e.g., Vp shown in FIG. 3) at one end thereof and to a switching transistor 200 at the other. The gate electrode of the switching transistor 200 is connected to the light detection scanning line 253. A desired line of light-detecting elements 120 for detecting the quantity of light emitted by the electroluminescent element 110 is selected by the light detection scanning line driver 254. The terminal of the switching transistor 200 which is not connected to the light-detecting element 120 is connected to a light detection signal line 260 which is connected to the charge amplifier 150. The charge amplifier 150 is connected to an AD converter 240.

In this arrangement, the detection of quantity of light is effected as follows.

Firstly, the scanning line driver 147 is controlled to select a desired line (e.g., uppermost line in FIG. 13). The electroluminescent elements 110 belonging to the line are allowed to emit light at the same time (intermittent driving as shown in FIG. 5C is effected).

During this procedure, the light detection scanning line driver 254 is controlled (e.g., Se10 shown in FIG. 13 is controlled) such that ON/OFF timing of all the switching transistors 200 belonging to the same line as that of the electroluminescent elements 110 which have emitted light is controlled. In this manner, the quantity of light emitted by the electroluminescent elements 110 belonging to the line are individually measured.

Subsequently, the charge stored in the capacitor CS140 on the basis of the quantity of light emitted is processed by the charge amplifier 150 and the AD converter 240 which differ every line, and then finally converted to 8 bit digital data.

The quantity of light emitted by the electroluminescent elements 110 belonging to the selected line thus detected is taken out to the exterior of the glass substrate 100 via wiring and interface which are not shown.

As shown in FIGS. 13 and 14, the display pixels 141 of the display device 220 each has an electroluminescent element 110 comprising an anode 111 made of ITO or the like, an electron-injecting layer, a buffer layer, a light-emitting layer and cathode (all not shown) formed sequentially on a glass substrate 100 having a thin film transistor and wiring formed thereon. In this structure, the anode and the electron-injecting layer are separately formed, the buffer layer and the light-emitting layer are integrally formed, and the cathode is formed in a striped form or an integral solid form.

The electroluminescent element 110 according to Embodiment 6 is an organic luminescent element.

The thin film transistor is formed by forming an organic semiconductor layer (polymer layer) on a glass substrate 100, covering the organic semiconductor layer by a gate insulating film, and then forming a gate electrode on the gate insulating film and a source-drain electrode via through-holes formed in the gate insulating film. A polyimide film or the like is spread over the thin film transistor to form an insulating film (flat layer). An anode (ITO), a molybdenum oxide layer, an electron-blocking layer, an organic semiconductor layer such as light-emitting layer, and a cathode (all not shown) are formed on the insulating film to form an electroluminescent element 110. While the light-detecting element 120, the retention capacitance CK251, the capacitor CS140 and wiring are formed underlying and thus are not shown in FIG. 14, they, too, are disposed in predetermined layers formed sequentially on the glass substrate 100. A plurality of display pixels 141 each composed of various thin film transistors and electroluminescent elements 110 are formed in matrix on the glass substrate 100 to constitute an active matrix type display device 220.

During the production procedure, a light-emitting layer is formed in an opening 255 formed in an image defining portion 114 formed by an insulating film by an ink jet method.

In some detail, a scanning line 143, a signal line 144, a driving transistor 130, a light-detecting element 120, a selective transistor 252, an anode 111 which is a pixel electrode, etc. are formed on the glass substrate 100. An image defining portion 114 is then formed on these layers to provide an opening 255. In Embodiment 6, the various transistors and light-detecting elements 120 each are formed by TFT made of polycrystalline silicon. The scanning line driver 147, the signal line driver, the common power supply line driver 149 and the light detection scanning line driver, too, can be formed by TFT. Such a driver comprises a logic circuit (e.g., shift register or latch). A relatively high speed circuit can be formed by a polycrystalline silicon.

Subsequently, a transition metal oxide layer such as MoO₃ is formed on the entire top surface of the opening 255 by a vacuum metallization method.

Thereafter, TFB is spread over the transition metal oxide layer by an ink jet method as necessary. The TFB layer may be spread over the entire surface similarly to the transition metal oxide layer or partly only on the area corresponding to the opening.

Subsequently, the coated material is subjected to drying step. A polymer luminescent material corresponding to the desired color (any of R, G and B) is then spread over the site corresponding to the opening 255 by an ink jet method.

Finally, a cathode which is not shown is formed opposed to the region where the display pixel 141 is formed.

In this arrangement, a display device having a high reliability which can be driven at a high speed can be provided.

An example of a lighting system having a plurality of electroluminescent elements 110 aligned two-dimensionally will be described below in connection with FIG. 14. Referring to the two-dimensional alignment of electroluminescent elements 110, an arrangement can be easily realized such that all the electroluminescent elements 110 are lighted/extinguished at the same time. However, even with such a simultaneous lighting/extinction arrangement, at least one of the electrodes (e.g., anode 111 as pixel electrode formed by ITO (see FIG. 1)) is preferably divisionally formed every electroluminescent element 110. This is because even when some factors cause the occurrence of defects in the display pixel, the defects retain in the display pixel 141, making it possible to enhance the yield in production of the entire lighting system. The lighting system having such an arrangement can be applied to e.g., ordinary household lighting fixtures. In this case, the lighting system can be formed to an extremely small thickness and thus can be easily installed not only on the ceiling but also on the wall.

Further, the emission pattern of the two-dimensionally aligned electroluminescent elements 110 can be easily controlled by providing arbitrary data. Moreover, the light-emitting region in the electroluminescent element 110 according to the invention can be formed to a size of about 40 μm square. Therefore, an application can be formed such that the lighting system is supplied with data to act also as a panel type display device. In this case, of course, the display pixels 141 need to be painted with red, green or blue depending on their position. However, the multi-color arrangement can be extremely easily carried out by an ink jet method.

The comparison of the related art lighting system and display device shows that the lighting system has a higher emission brightness than the display device. However, the electroluminescent elements 110 according to the invention each have a uniform distribution of quantity of light emitted (in-plane distribution) and hence a prolonged life and thus can act also as a lighting system. In this case, a mechanism is required for adjusting emission brightness due to difference in function (i.e., mode of use) between lighting system and display device. This mechanism can be realized, e.g., by controlling the driving current to adjust the emission brightness of the various electroluminescent elements 110. In some detail, in the case where the light-emitting device is used as a lighting system, all the electroluminescent elements 110 may be driven with a larger current. In the case where the light-emitting device is used as a display device, the various electroluminescent elements 110 may be driven with a small current which is controlled according to gradation (i.e., according to image data). In this application, the power supply for the case where the light-emitting device acts as a lighting device and the power supply for the case where the light-emitting device acts as a display device may be the same. However, in the case where the dynamic range of a digital-analog converter for controlling the driving current is too great to provide a sufficient number of gradations as display device, it is preferably arranged such that the power supply (not shown) connected to the common power supply line 145 shown in FIGS. 13 and 14 is switched depending on the mode of use. Of course, also in the mode of use as lighting system, the embodiment requiring brightness control (i.e., lighting system having a light adjustment mechanism) can be easily coped with by the aforementioned current control depending on gradation. Further, the electroluminescent element 110 of the invention can be formed not only on the glass substrate 100 but also on a resin substrate such as PET and thus can be used as lighting system for various illumination purposes.

An organic transistor made of an organic film may be formed on the thin film semiconductor layer of the thin film transistor. Further, a structure having an electroluminescent element 110 laminated on a thin film transistor or a structure having a thin film transistor laminated on an electroluminescent element 110 is useful. These structures can be extremely easily produced by an ink jet method.

In addition, in order to obtain a high quality electroluminescent display device, an electroluminescent substrate having an electroluminescent element formed thereon and a TFT substrate having TFT, capacitor, wiring, etc. formed thereon may be stuck to each other in such an arrangement that the electrode of the electroluminescent substrate and the electrode of the TFT substrate are connected to each other via a connection bank.

While the foregoing description has been made with reference to the case where the electroluminescent element is driven with dc current, the electroluminescent element may be driven with ac voltage or ac current or pulse wave.

### Embodiment 7

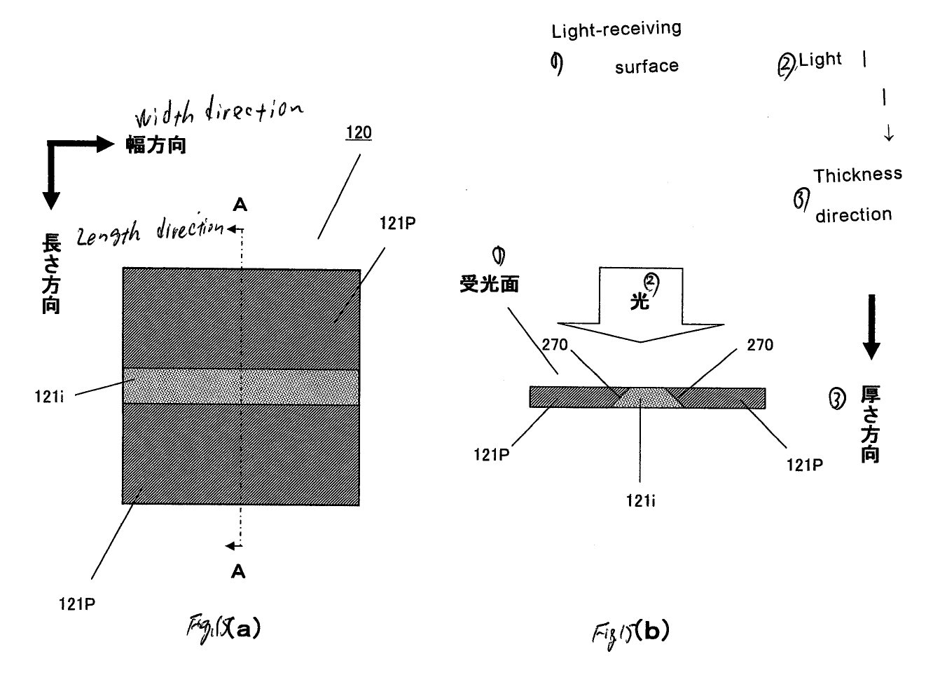

FIG. 15A is a plan view of a light-detecting element 120 according to Embodiment 7. FIG. 15B is a sectional view of the light-detecting element 120 according to Embodiment 7 taken on the line A-A of FIG. 15A.

As shown in FIGS. 15A and 15B, the width, length direction and thickness direction of the light-detecting element 120 are defined as viewed on its plan view and sectional view.

In the following description, the source electrode 121S and the drain electrode 121D (see FIG. 1) described in Embodiment 1 are altogether referred to as “good conductor region 121P”

An improved configuration of the light-detecting element 120 will be described in connection with FIGS. 15A and 15B in combination with FIG. 1.

The light-detecting element 120 is formed by a channel region 121i which is a photoconductor and a good conductor region 121P having the same thickness as that of the channel region 121i. The good conductor region 121P is connected to the source electrode 125S and the drain electrode 125D of the light-detecting element 120 via through-holes (see FIG. 1). The good conductor region 121P is connected to the entire surface of the two sides of the channel region 121i to which it is opposed. As can be seen in the plan view of FIG. 15a and the A-A sectional view of FIG. 15B, the contact surface 270 of the channel region 121i with the good conductor region 121P is formed parallel to the width direction and oblique to the thickness direction.

In some detail, the light-detecting element 120 according to Embodiment 7 is formed by a photoconductor (channel region 121i) and a good conductor (good conductor region 121P) disposed adjacent to a plurality of sides (i.e., two sites) of the photoconductor. The contact surface of the photoconductor with the good conductor has a larger area than the section of the photoconductor taken on the line parallel to the good conductor.

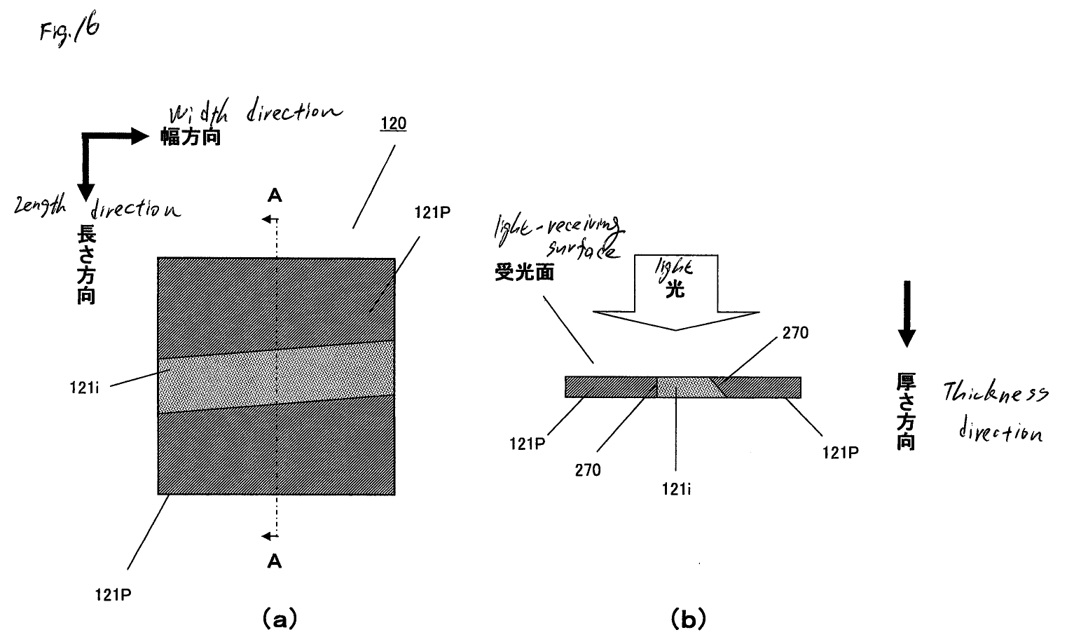

FIGS. 16A and 16B each are a diagram illustrating another configuration of the light-detecting element 120 according to Embodiment 7.

As shown in FIGS. 16A and 16B, the contact surface 270 may be formed oblique to the width direction/length direction or oblique to the width direction/length direction and the thickness direction.

As mentioned above, in the case where the contact surface 270 of the channel region 121i with the good conductor region 121P is formed oblique to the width direction/length direction or the thickness direction of the light-detecting element 120, the area of the contact surface 270 of the channel region 121i with the good conductor region 121P is larger. In this arrangement, the electrical resistance of the channel region 121i is smaller than in the case where the contact surface 270 is formed parallel to the width direction and the thickness direction of the light-detecting element 120, i.e., in the case where the contact surface 270 of the channel region 121i with the good conductor region 121P has the minimum area. In this arrangement, an output having an excellent S/N ratio and a reduced heat noise can be obtained.

In the light-detecting element 120 according to Embodiment 7, a substantially rectangular semiconductor island region A_{R}, a channel region 121i and a good conductor region 121P are formed by a continuous process. As the material of the semiconductor island region A_{R} there is used a polycrystalline silicon as already described. The material of the channel region 121i is a polycrystalline silicon which is the same as the polycrystalline silicon constituting the semiconductor island region A_{R} as a base material. As the material of the good conductor region 121P there is used a polycrystalline silicon doped with a pentavalent element such as phosphor. A process for the formation of the channel region 121i and the good conductor region 121P will be described hereinafter in connection with FIG. 15.

Firstly, a photosensitive resin is spread over the entire surface of the semiconductor island region A_{R}. A masking pattern is then put on the photosensitive resin. The masking pattern is obtained by vacuum-metallizing a transparent quartz glass with a metal such as chromium. The shape of the metal deposit has the same shape as the planar shape of the lower surface of the channel region 121i. Subsequently, the photosensitive resin having the masking pattern put thereon is irradiated with ultraviolet rays. The photosensitive resin under the metal deposit is not irradiated with ultraviolet rays. Therefore, when the masking pattern is removed from the surface of the photosensitive resin, the photosensitive resin then has an irradiated area and an unirradiated area formed thereon. When irradiated with ultraviolet rays, the photosensitive resin becomes soluble in the developer.

Subsequently, when the photosensitive resin thus irradiated with ultraviolet rays is dipped in the developer, the photosensitive resin is dissolved in the developer and removed from the surface of the semiconductor island region A_{R} at the area irradiated with ultraviolet rays. Accordingly, only the photosensitive resin mask having the same surface shape as the lower surface of the channel region 121i is left on the surface of the semiconductor island region A_{R}. Finally, the semiconductor island region A_{R} is entirely irradiated with a beam of ion of the atom to be added (doping). Since the mask blocks the ion beam, the semiconductor directly under the mask becomes a photoconductive channel region 121i. On the other hand, the unmasked area of the semiconductor island region A_{R} is exposed to ion beam and thus is doped with atom to form a good conductor region 121P.

The semiconductor directly under the mask is not directly doped with atom. However, at the mask border area, the pentavalent atoms which have penetrated the unmasked area undergoes diffusion to move to the masked area. In Embodiment 7, the oblique contact surface 270 as shown in FIG. 15B can be formed by making the use of the diffusion phenomenon of atoms which have penetrated the semiconductor and adjusting the output or emission time of ion beam to be applied to the semiconductor depending on the site.

When the mask is removed from the semiconductor island region A_{R} thus irradiated with ion beam, the light-detecting element 120 shown in FIG. 15 is then completed.

While the contact surface 270 of the light-detecting element 120 according to Embodiment 7 is formed oblique to the thickness direction of the light-detecting element 120, it may be formed oblique to the width/length direction of the light-detecting element 120 as shown in FIG. 6. The material of the semiconductor island region A_{R} which is the base of the light-detecting element 120 may be an amorphous silicon. While the light-detecting element 120 comprises a pentavalent atom as a dopant of the good conductor region 121P (additive atom), a trivalent atom may be used as a dopant. The back side of the light-receiving surface of the light-detecting element 120 according to Embodiment 7 may be used as a light-receiving surface.

The width of the channel region 121i is preferably as narrow as possible to assure a desired potential gradient.

### Embodiment 8

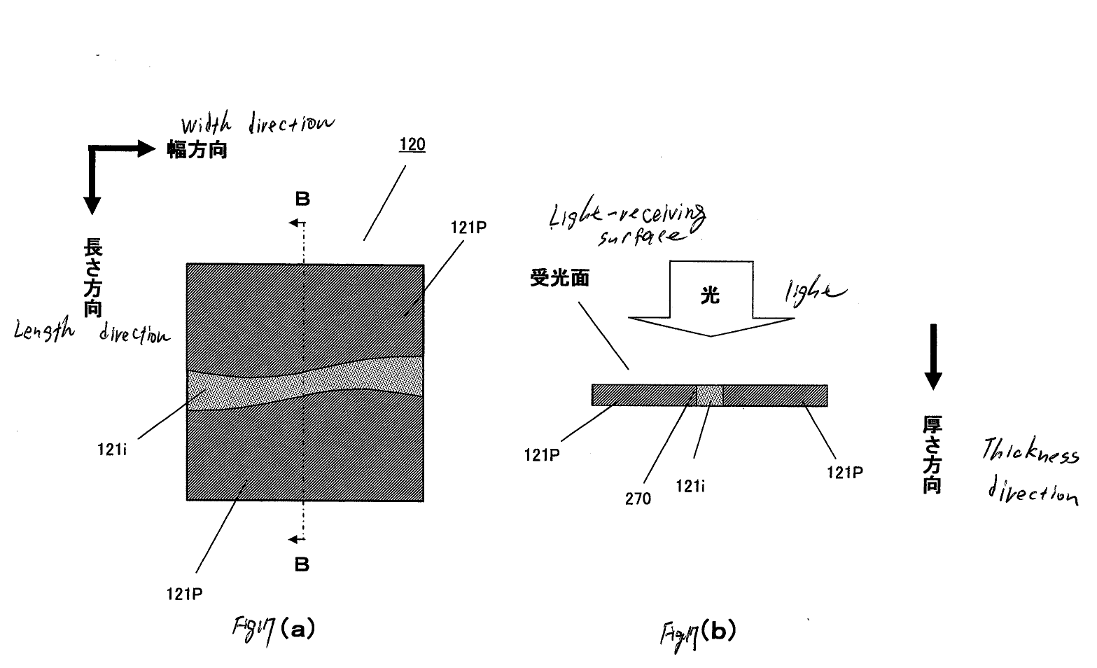

FIG. 17A is a plan view of a light-detecting element 120 according to Embodiment 8 and FIG. 17B is a sectional view of the light-detecting element 120 according to Embodiment 8 taken on the line B-B of FIG. 17A. In Embodiment 8, too, the width/length direction and the thickness direction are defined with respect to the plan and section of the light-detecting element 120 as shown in FIGS. 17A and 17B.

The light-detecting element 120 is composed of a channel region 121i and a good conductor region 121P having the same thickness as the channel region 121i. The good conductor region 121P is connected to the source electrode 125S and the drain electrode 125D of the light-detecting element 120 via through-holes (see FIG. 1). The good conductor region 121P is connected to the entire surface of the two sides of the channel region 121i to which it is opposed. As can be seen in FIGS. 17A and 17B, the contact surface 270 of the channel region 121i with the good conductor region 121P is in a curved form.

In the case where the contact surface 270 of the channel region 121i with the good conductor region 121P is in a curved form, the electrical resistance of the channel region is smaller than that in the case where the contact surface 270 is formed parallel to the width direction and the thickness direction of the light-detecting element 120, that is, the area of the contact surface 270 of the channel region 121i with the good conductor region 121P is minimized, making it possible to obtain an output having a reduced heat noise and hence an excellent S/N ratio.

In the light-detecting element 120 according to Embodiment 8, the longitudinal width of the channel region 121i is not constant. The light-detecting element 120 having a channel region 121i the longitudinal with of which is not constant has a local difference in the electrical resistance and potential gradient of the channel region 121i. Accordingly, the detection signal outputted by the light-detecting element 120 according to Embodiment 8 when it senses light varies in its magnitude depending on the position at which the light is incident in the channel region 121i. By making the use of the difference in magnitude of detection signal depending on the position at which the light is incident, the light-detecting element 120 according to Embodiment 8 can be applied, e.g., to position detecting sensor.

In the light-detecting element 120 according to Embodiment 8, too, the channel region 121i and the good conductor region 121P as sensor electrode are formed from a substantially rectangular semiconductor island region A_{R} as in the case of the light-detecting element 120 according to Embodiment 7. As the material of semiconductor there is used a polycrystalline silicon. The material of the channel region 121i is a polycrystalline silicon which is the same as the polycrystalline silicon constituting the semiconductor island region A_{R} as a base. Further, the material of the good conductor region 121P is a polycrystalline silicon doped with a pentavalent element such as phosphor. The process for the formation of the channel region 121i and the good conductor region 121P is the same as the process for the formation of the light-detecting element 120 according to Embodiment 7.

### Embodiment 9

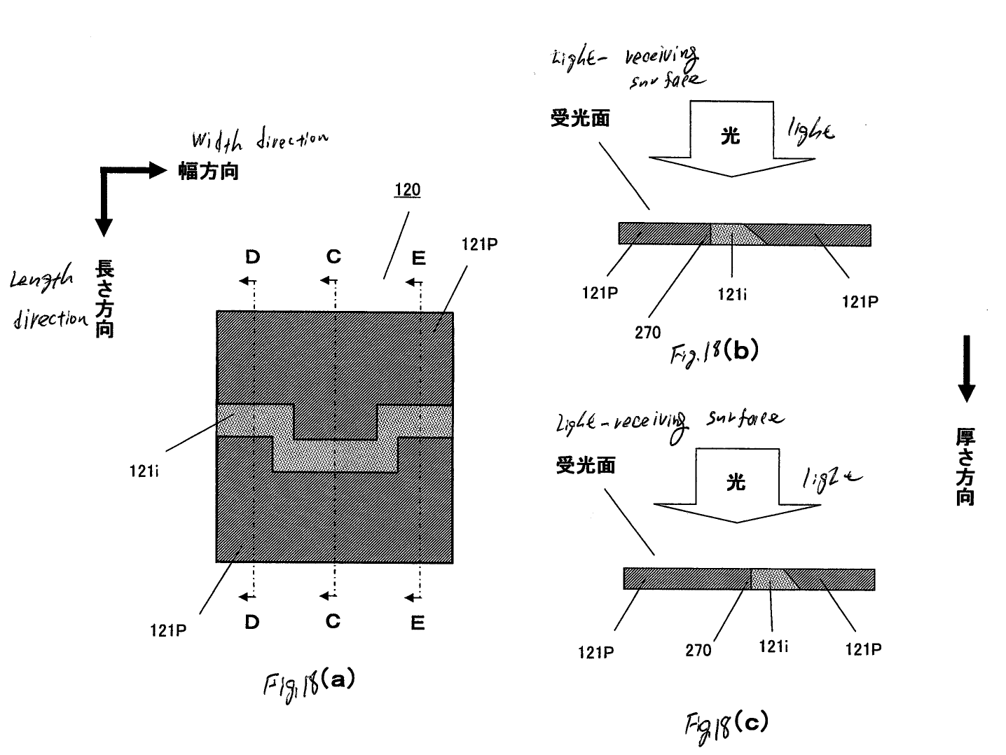

FIG. 18 is a plan view of a light-detecting element 120 according to Embodiment 9, FIG. 18B is a sectional view of the light-detecting element 120 according to Embodiment 9 taken on the line C-C of FIG. 18 and FIG. 18C is a sectional view of the light-detecting element 120 according to Embodiment 9 taken on the line D-D and the line E-E of FIG. 18.

In Embodiment 9, too, the width/length direction and the thickness direction are defined with respect to the plan and section of the light-detecting element 120 as shown.

The light-detecting element 120 is composed of a channel region 121i and a good conductor region 121P having the same thickness as the channel region 121i. The good conductor region 121P is connected to the source electrode 125S and the drain electrode 125D of the light-detecting element 120 via through-holes (see FIG. 1). The good conductor region 121P is connected to the entire surface of the two sides of the channel region 121i to which it is opposed. As shown in FIGS. 18A, 18B and 18C, the contact surface of the channel region 121i with the good conductor region 121P has a zigzag configuration composed of a vertical surface at one side thereof and a zigzag configuration composed of a surface oblique to the thickness direction of the light-detecting element at the other side thereof.

In the case where the contact surface 270 of the channel region 121i with the good conductor region 121P is in a zigzag configuration composed of a vertical surface or oblique surface, the electrical resistance of the channel region is smaller than that in the case where the contact surface 270 is formed parallel to the width direction and the thickness direction of the light-detecting element 120, that is, the area of the contact surface 270 of the channel region 121i with the good conductor region 121P is minimized, making it possible to obtain an output having a reduced heat noise and hence an excellent S/N ratio.

In the light-detecting element 120 according to Embodiment 9, the longitudinal width of the channel region 121i is not constant. The light-detecting element 120 having a channel region 121i the longitudinal with of which is not constant has a local difference in the electrical resistance and potential gradient of the channel region 121i. Accordingly, the detection signal outputted by the light-detecting element 120 according to Embodiment 9 when it senses light varies in its magnitude depending on the position at which the light is incident in the channel region 121i. By making the use of the difference in magnitude of detection signal depending on the position at which the light is incident, the light-detecting element 120 according to Embodiment 9 can be applied, e.g., to position detecting sensor.

In the light-detecting element 120 according to Embodiment 9, too, the channel region 121i and the good conductor region 121P as sensor electrode are formed from a substantially rectangular semiconductor island region A_{R} by a continuous process as in Embodiments 7 and 8. As the material of semiconductor there is used a polycrystalline silicon. The material of the channel region 121i is a polycrystalline silicon which is the same as the polycrystalline silicon constituting the semiconductor island region A_{R} as a base. Further, the material of the good conductor region 121P is a polycrystalline silicon doped with a pentavalent element such as phosphor. The process for the formation of the channel region 121i and the good conductor region 121P is the same as in Embodiments 7 and 8.

### Embodiment 10

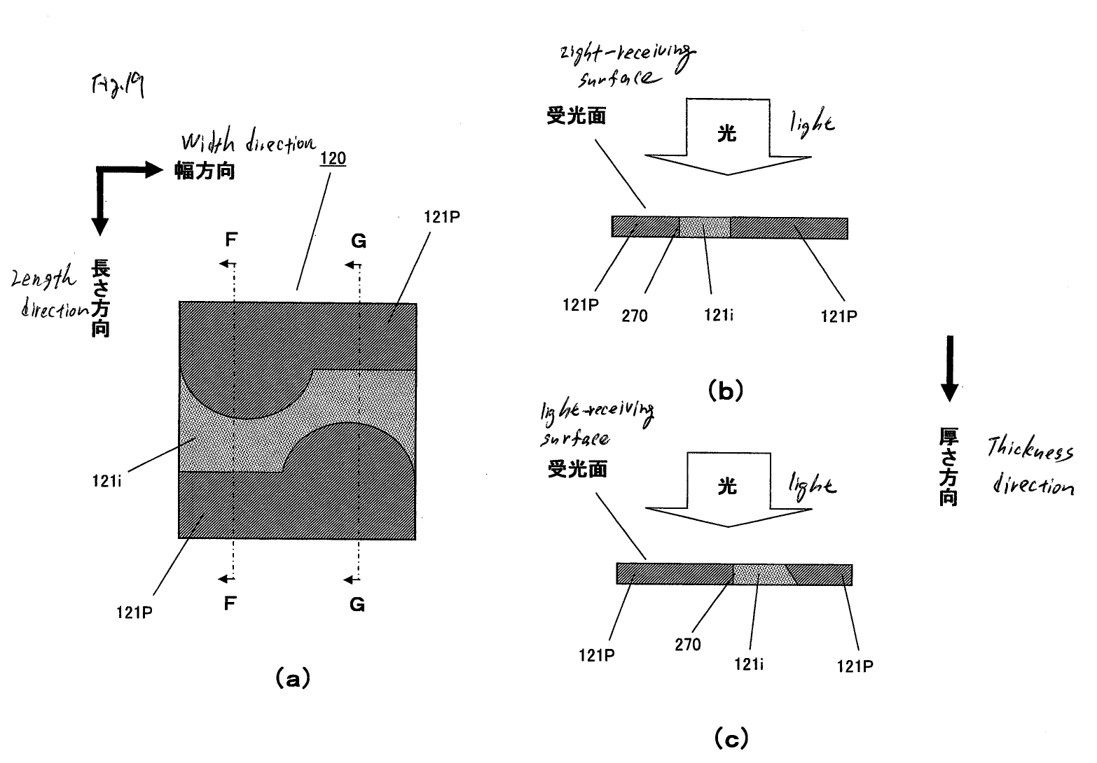

FIG. 19A is a plan view of a light-detecting element 120 according to Embodiment 10, FIG. 19B is a sectional view of the light-detecting element 120 according to Embodiment 10 taken on the line F-F of FIG. 19A and FIG. 19C is a sectional view of the light-detecting element 120 according to Embodiment 10 taken on the line G-G of FIG. 19A.

In Embodiment 10, too, the width/length direction and the thickness direction are defined with respect to the plan and section of the light-detecting element 120 as shown in FIG. 19.

The light-detecting element 120 is composed of a channel region 121i and a good conductor region 121P having the same thickness as the channel region 121i. The good conductor region 121P is connected to the source electrode 125S and the drain electrode 125D of the light-detecting element 120 via through-holes (see FIG. 1). The good conductor region 121P is connected to the entire surface of the two sides of the channel region 121i to which it is opposed. As can be seen in FIGS. 18A, 18B and 18C, the contact surface of the channel region 121i with the good conductor region 121P has a configuration composed of a curved surface and an oblique surface and a configuration composed of a curved surface and a flat surface.

In the case where the contact surface 270 of the channel region 121i with the good conductor region 121P has a configuration composed of a curved surface and an oblique surface and a configuration composed of a curved surface and a flat surface, the electrical resistance of the channel region 121i is smaller than that in the case where the contact surface 270 is formed parallel to the width direction and the thickness direction of the light-detecting element 120, that is, the area of the contact surface 270 of the channel region 121i with the good conductor region 121P is minimized, making it possible to obtain an output having a reduced heat noise and hence an excellent S/N ratio.

In the light-detecting element 120 according to Embodiment 10, the longitudinal width of the channel region 121i is not constant. The light-detecting element 120 having a channel region 121i the longitudinal with of which is not constant has a local difference in the electrical resistance and potential gradient of the channel region 121i. Accordingly, the detection signal outputted by the light-detecting element 120 according to Embodiment 10 when it senses light varies in its magnitude depending on the position at which the light is incident in the channel region 121i. By making the use of the difference in magnitude of detection signal depending on the position at which the light is incident, the light-detecting element 120 according to Embodiment 10 can be applied, e.g., to position detecting sensor.

In the light-detecting element 120 according to Embodiment 10, too, the channel region 121i and the good conductor region 121P as sensor electrode are simultaneously formed from a substantially rectangular semiconductor island region A_{R} as in the case of the light-detecting element 120 according to Embodiments 7 to 9. As the material of semiconductor there is used a polycrystalline silicon. The material of the channel region 121i is a polycrystalline silicon which is the same as the polycrystalline silicon constituting the semiconductor island region A_{R} as a base. Further, the material of the good conductor region 121P is a polycrystalline silicon doped with a pentavalent element such as phosphor. The process for the formation of the channel region 121i and the good conductor region 121P is the same as the process for the formation of the light-detecting element 120 according to Embodiments 2, 3 and 7.

### Embodiment 11

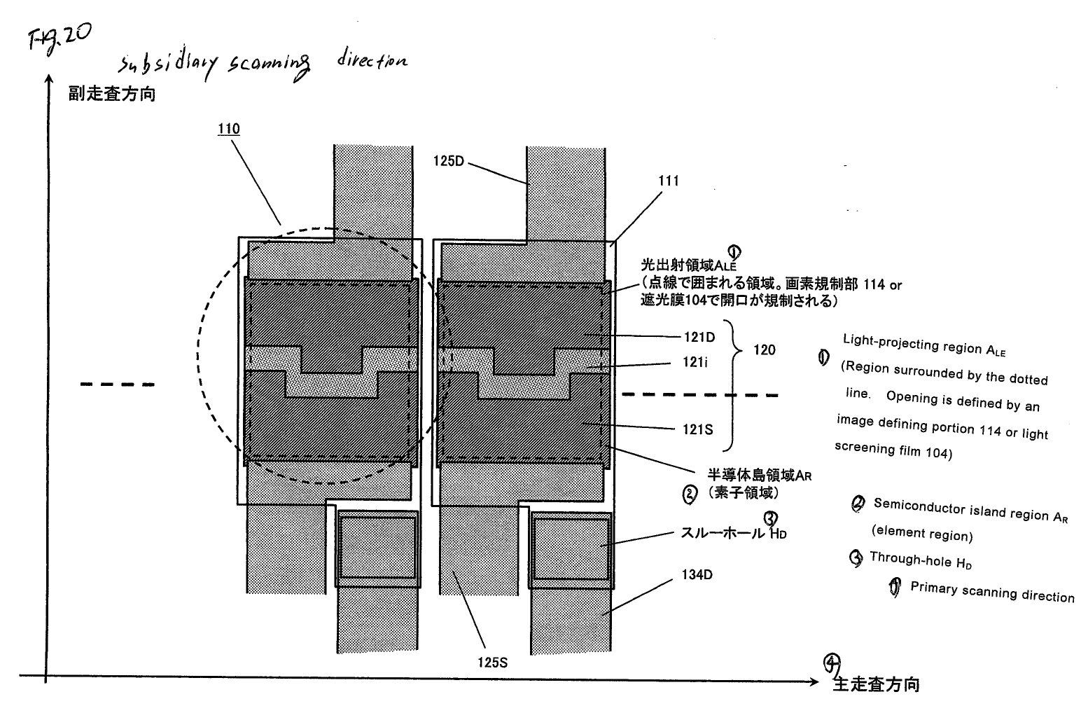

FIG. 20 is a configurational diagram illustrating the configuration of a part of a light head having a light-detecting element 120 according to Embodiment 11 in the vicinity of the light-detecting element 120.

In Embodiment 11, as the light-detecting element 120 there is used one described in Embodiment 9. Therefore, the configuration of the light-detecting element 120 itself will not be described. As shown in FIG. 20, the light head according to Embodiment 11 is a light head comprising an electroluminescent element as a light source. The light head is composed of a plurality of electroluminescent elements 110 aligned in the primary scanning direction (direction of element line). One light-detecting element 120 is disposed for one light-projecting region. In this arrangement, the quantity of light emitted by the various electroluminescent elements 110 can be independently measured by the light-detecting element 120. In other words, the quantity of light emitted by a plurality of electroluminescent elements 110 can be simultaneously measured, making it possible to drastically reduce the measuring time.

### Embodiment 12

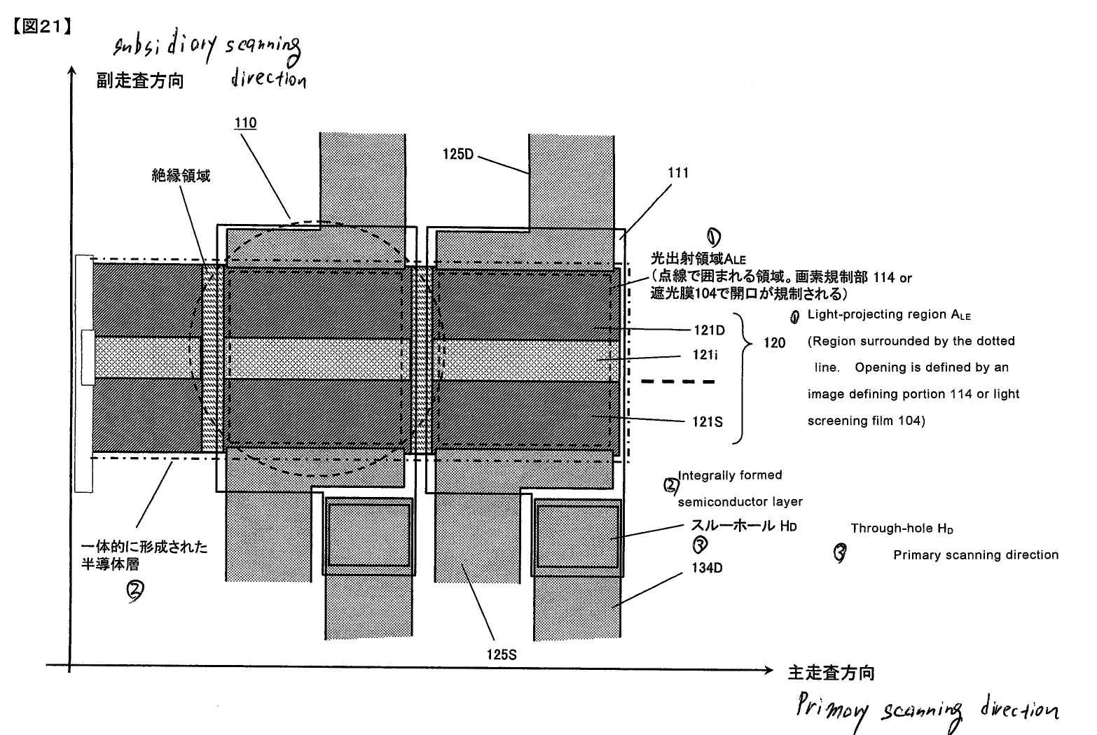

FIG. 21 is a configurational diagram illustrating the configuration of a part of a light head having a light-detecting element 120 according to Embodiment 12 in the vicinity of the light-detecting element 120.

While Embodiments 1 and 2, etc. have been described with reference to the case where the semiconductor region is in an island form (semiconductor island region A_{R}), the semiconductor layer constituting the light-detecting element 120 may be integrally formed.

In other words, the light-detecting element 120 is formed in a semiconductor layer formed integrally with a substrate 100 (that is, an electrical semiconductor island region A_{R} is formed by TFT production process). The light-projecting region A_{LE} of the light-emitting element 110 is disposed inside the light-detecting element 120 formed in the semiconductor layer. The lower electrode (anode 111) of the light-emitting element 110 is formed covering a part of the semiconductor layer. Further, the light-projecting region A_{LE} is formed smaller than the lower electrode (anode 111).

In order to realize such a configuration, the integrally formed polycrystalline silicon (integral semiconductor layer 281) may be selectively insulated by anodization or doping with oxygen ion so that the semiconductor region is divided into elements by an electrically insulating region 280. In other words, the active regions 282 separated by the insulating region 280 constitute the light-detecting element 120. In this case, the active region 282 and the insulating region 280 disposed at the peripheral edge thereof constitute the same flat surface, making it possible to dispose the light-projecting region A_{LE} on a flat surface. In this arrangement, the formation of a desired element can be realized while maintaining the flatness of the surface of the light-detecting element 120.

While FIG. 21 depicts how an integral semiconductor layer 281 formed extending in the primary scanning direction is separated by an insulating region 280 to form active regions 282, the integral semiconductor layer 281 may be formed large also in the subsidiary scanning direction so that the active region 282 is surrounded by the insulating region 280 (except the sites of source electrode 125S and drain electrode 125D).

The case where this configuration is applied to the light-emitting device according to Embodiment 1 will be described in connection with FIG. 21 in combination with FIG. 1. While the semiconductor island regions constituting the driving transistor 130 and the light-detecting element 120 is shown in island form in FIG. 1, these semiconductor regions are integral from the configurational standpoint of view in the present embodiment. As mentioned above, the semiconductor regions are electrically separated by doping with oxygen ion or the like.

In this case, as the substrate there is used an insulating light-transmitting substrate. The light-detecting element 120 is composed of a semiconductor element having a semiconductor layer formed on the light-transmitting substrate as active region 282. In this configuration, the light-emitting element 110 comprises a first electrode (anode 111) formed by a light-transmitting electrically-conductive film (e.g., ITO) formed covering the semiconductor layer, a light-emitting layer 112 formed on the first electrode and a second electrode (cathode 113) formed on the light-emitting layer 112, whereby an electric field is applied between the first electrode and the second electrode to allow the light-emitting layer 112 to emit light.

The case where this configuration is applied to the light-emitting device shown in Embodiment 2 will be described in connection with FIG. 21 in combination with FIG. 7. While the semiconductor island regions constituting the driving transistor 130 and the light-detecting element 120 is shown in island form in FIG. 7, these semiconductor regions are integral from the configurational standpoint of view in the present embodiment. As mentioned above, the semiconductor regions are electrically separated by doping with oxygen ion or the like.

In this case, as the substrate there is used an insulating substrate having a reflective surface. The light-detecting element 120 is composed of a semiconductor element having a semiconductor layer formed on the substrate having a reflective surface as active region 282. In this configuration, the light-emitting element 110 comprises a first electrode (anode 111) formed by a light-transmitting electrically-conductive film (e.g., ITO) formed covering the semiconductor layer, a light-emitting layer 112 formed on the first electrode and a second electrode (cathode 113a, 113b) formed on the light-emitting layer 112, whereby an electric field is applied between the first electrode and the second electrode to allow the light-emitting layer 112 to emit light.

In accordance with the light-emitting device of the invention and the process for the production thereof, the distribution of quantity of light (in-plane distribution) emitted by electroluminescent elements 110 as light-emitting element can be made extremely uniform and the quantity of light emitted can be accurately controlled on the basis of the quantity of light detected. Thus, the light-emitting device of the invention and the process for the production thereof can be applied to light head and image forming device having light head incorporated therein, e.g., copying machine, printer, multifunction printer, facsimile.

In accordance with the light-emitting device of the invention and the process for the production thereof, a light-emitting layer can be formed extremely uniformly on a light quantity detecting element, making it possible to prolong the life of the electroluminescent element as a light-emitting element and accurately control the quantity of light emitted on the basis of the quantity of light detected. Thus, the light-emitting device of the invention and the process for the production thereof can be applied to display devices such as display and television and lighting systems such as illumination sign and lighting fixture.

This application is based upon and claims the benefit of priority of Japanese Patent Application No 2006-005910 filed on Jan. 13, 2006 Japanese Patent Application No 2006-068797 filed on. Mar. 14, 2006. Japanese Patent Application No 2006-117109 filed on Apr. 20, 2006 the contents of which are incorporated herein by reference in its entirety.

1. A light-emitting device, comprising:
a light-emitting element; and
a light-detecting element for detecting light emitted by the light-emitting element laminated on a substrate;
wherein the light-emitting element has a light-projecting region provided on a flat surface thereof.

2. The light-emitting device as defined in claim 1, wherein the light-detecting element and the light-emitting element are formed in this order on the substrate and the flat surface is formed by the light-detecting element.

3. The light-emitting device as defined in claim 1, wherein the light-emitting element is formed laminated on the top of the light-detecting element formed on the substrate and the element region of the light-detecting element is formed larger than the light-projecting region so as to cover the light-projecting region of the light-emitting element.

4. The light-emitting device as defined in claim 3, wherein the light-detecting element is formed in an island-shaped semiconductor region formed on the substrate, the light-projecting region of the light-emitting element is formed in the semiconductor region and the lower side electrode of the light-emitting element is formed covering the semiconductor region.

5. The light-emitting device as defined in claim 1, wherein the light-emitting element is laminated on the top of the light-detecting element formed on the substrate and the outer edge of the element region of the light-detecting element is formed disposed outside the light-projecting region of the light-emitting element.

6. The light-emitting device as defined in claim 1, wherein the light-emitting element is formed in a semiconductor layer formed integrally on the substrate, the light-projecting region of the light-emitting element is formed in the semiconductor layer, the lower side electrode of the light-emitting element is formed on a part of the top of the semiconductor layer and the light-projecting region is defined smaller than the lower side electrode.

7. The light-emitting device as defined in claim 4, wherein the substrate is a light-transmitting substrate having insulating properties, the light-detecting element is a semiconductor element having a semiconductor layer formed on the light-transmitting substrate as an active region, the light-emitting element comprises a first electrode formed by a light-transmitting electrically-conductive film formed covering the semiconductor layer, a light-emitting layer formed on the first electrode and a second electrode formed on the light-emitting layer and the light-emitting layer is allowed to emit light when an electric field is applied between the light-emitting element and the first electrode.

8. The light-emitting device as defined in claim 4, wherein the substrate is a substrate having insulating properties and a reflective surface, the light-detecting element is a semiconductor element having a semiconductor layer formed on the substrate as an active region, the light-emitting element comprises a first electrode formed by a light-transmitting electrically-conductive film formed covering the semiconductor layer, a light-emitting layer formed on the first electrode and a second electrode formed on the light-emitting layer and the light-emitting layer is allowed to emit light when an electric field is applied between the light-emitting element and the first electrode.

9. The light-emitting device as defined in claim 7, wherein the semiconductor element is a diode.

10. The light-emitting device as defined in claim 7, wherein the semiconductor element is a transistor which is formed by the first electrode of the light-emitting element as a gate electrode.

11. The light-emitting device as defined in claim 10, wherein the semiconductor element is a thin film transistor formed by a polycrystalline silicon or amorphous silicon, the first electrode is formed with the interposition of an insulating film covering the semiconductor layer, the thin film transistor forms an electric field effect transistor having the first electrode of the light-emitting element as a gate electrode and the insulating film as a gate insulating film and the gate insulating film is arranged having a thickness such that a voltage drop occurs to an extent such that the dispersion of potential of the first electrode can be neglected.

12. The light-emitting device as defined in claim 1, wherein the light-projecting region is defined by an opening formed in an insulating film provided interposed between the first electrode or second electrode and the light-emitting layer.

13. The light-emitting device as defined in claim 1, wherein the light-projecting region is defined by an opening formed in a light-screening film provided closer to the light emission side than the light-projecting region of the light-emitting element.

14. The light-emitting device as defined in claim 1, wherein the light-emitting element is disposed in a number of one every the light-projecting region.

15. The light-emitting device as defined in claim 1, wherein the light-emitting element is an organic electroluminescent element comprising an organic semiconductor layer as a light-emitting layer or an inorganic electroluminescent element comprising an inorganic semiconductor layer as a light-emitting layer.

16. The light-emitting device as defined in claim 1, comprising a shading correction portion for correcting the quantity of light from the light-emitting element according to the output of the light-detecting element.

17. The light-emitting device as defined in claim 1, wherein the light-detecting element is formed by a photoconductor and a good conductor provided adjacent to a plurality of sides of the photoconductor and the joint area of the photoconductor with the good conductor is arranged larger than the section of the photoconductor taken on the line parallel to the good conductor.

18. The light-emitting device as defined in claim 17, wherein the joint area is formed by a surface oblique to the width direction, length direction and thickness direction of the light-detecting element.

19. The light-emitting device as defined in claim 18, wherein the oblique surface is formed by a curved surface.

20. A method for the production of a light-emitting element comprising at least the following steps:
i) A step of forming a light-detecting element having an island-shaped semiconductor region on a substrate; and
ii) A step of forming a light-emitting element superimposed on the semiconductor region on the top of a flat portion of the semiconductor region, wherein the step ii) comprises the following steps:
a) A step of forming a driving electrode of the light-emitting element covering the entire part of the island-shaped semiconductor region;
b) A step of covering a part of the driving electrode by an insulating film and forming an opening at least inside the flat portion to define a light-emitting region;
c) A step of spreading a luminescent material over a portion including at least the opening to form a light-emitting layer; and
d) A step of forming other electrode made of a metal as a main material on the spread of the luminescent material such that the light-emitting layer is interposed between the other electrode and the driving electrode to form the light-emitting element.
